(19) United States
(12) Patent Application Publication
(10) Pub. No.: US 2024/0090228 A1
(43) Pub. Date: Mar. 14, 2024

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si, Gyeonggi-do (KR)

(72) Inventors: Hoyoung CHOI, Suwon-si (KR); Sanghun CHUN, Suwon-si (KR); Jeehoon HAN, Suwon-si (KR)

(21) Appl. No.: 18/300,975

(22) Filed: Apr. 14, 2023

(30) Foreign Application Priority Data
Sep. 13, 2022 (KR) 10-2022-0114975

(51) Int. Cl. H10B 43/40; H01L 23/522; H01L 23/528; H01L 25/065; H10B 41/10; H10B 41/27; H10B 41/35; H10B 41/40; H10B 43/10; H10B 43/27; H10B 43/35; H10B 80/00

(52) U.S. Cl. CPC H10B 43/40; H01L 23/5226; H01L 23/5283; H01L 25/0652; H10B 41/10; H10B 41/27; H10B 41/35; H10B 41/40; H10B 43/10; H10B 43/27; H10B 43/35; H10B 80/00

(57) ABSTRACT

A semiconductor memory device comprises a first substrate, a peripheral circuit structure, and a cell array structure including a cell array region and a cell array contact region. The cell array structure includes a second substrate, a stack structure including first and second stack structures, a vertical channel structure in the cell array region, and a cell contact plug in the cell array contact region. The cell contact plug includes a first pillar part and a first protrusion part. At the level of the top surface of the first protrusion part, a first width is given as a maximum diameter at an outer perimeter of the first protrusion part. At a level of an interface between the first and second stack structures, a second width is given as a maximum width of the vertical channel structure. The first width is greater than the second width.

### CROSS-REFERENCE TO RELATED APPLICATION

This U.S. nonprovisional application claims priority under 35 U.S.C § 119 to Korean Patent Application No. 10-2022-0114975 filed on Sep. 13, 2022 in the Korean Intellectual Property Office, the disclosure of which is hereby incorporated by reference in its entirety.

### BACKGROUND

The present inventive concepts relate to three-dimensional semiconductor device, a method of fabricating the same, and an electronic system including the same.

It is necessary to have a semiconductor device capable of storing a large amount of data in an electronic system which requires data storage. Semiconductor devices have been highly integrated to meet high performance and low manufacturing cost which are required by customers. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

Some embodiments of the present inventive concepts provide a three-dimensional semiconductor memory device whose reliability and electrical properties are improved and a method of fabricating the same.

An object of the present inventive concepts is not limited to the mentioned above, and other objects which have not been mentioned above will be clearly understood to those skilled in the art from the following description.

According to some embodiments of the present inventive concepts, a three-dimensional semiconductor memory device may comprise: a first substrate; a peripheral circuit structure on the first substrate; and a cell array structure on the peripheral circuit structure, the cell array structure including a cell array region and a cell array contact region. The cell array structure may include a second substrate; a stack structure including a first stack structure and a second stack structure that are stacked on the second substrate, each of the first and second stack structures including interlayer dielectric layers and gate electrodes that are alternately disposed; a vertical channel structure in the cell array region, the vertical channel structure penetrating at least a portion of the stack structure and a portion of the second substrate; and a cell contact plug in the cell array contact region, the cell contact plug penetrating at least a portion of the stack structure and a portion of the second substrate. The cell contact plug may include: a first pillar part that extends in a direction perpendicular to a top surface of the first substrate; and a first protrusion part that protrudes from the first pillar part in a first direction parallel to the top surface of the first substrate, wherein the first protrusion part and the first pillar part may comprise a single unitary piece, wherein the first protrusion part may have a circular annular shape or a polygonal annular shape when viewed in plan, wherein a top surface of the first protrusion part may be at a same distance as a distance of a top surface of the first stack structure from the top surface of the first substrate, wherein, the first protrusion part may have a first width at the top surface of the first protrusion part, and the first width may be a maximum diameter at an outer perimeter of the first protrusion part, wherein, the vertical channel structure may have a second width at an interface between the first stack structure and the second stack structure, and the second width may be a maximum width of the vertical channel structure in the first direction, and wherein the first width may be greater than the second width.

According to some embodiments of the present inventive concepts, a semiconductor memory device may comprise: a first substrate; a peripheral circuit structure on the first substrate; and a cell array structure on the peripheral circuit structure, the cell array structure including a cell array region and a cell array contact region. The cell array structure may include: a stack structure including a first stack structure and a second stack structure that are stacked on the peripheral circuit structure, each of the first and second stack structures including interlayer dielectric layers and gate electrodes that are alternately disposed; a second substrate on the second stack structure; a cell contact plug in the cell array contact region, the cell contact plug penetrating at least a portion of the stack structure and a portion of the second substrate; and a dummy vertical structure spaced apart from the cell contact plug, the dummy vertical structure penetrating at least a portion of the stack structure and a portion of the second substrate in the cell array contact region. The cell contact plug may include: a first pillar part that extends in a direction perpendicular to a top surface of the first substrate; and a first protrusion part that protrudes from the first pillar part in a first direction parallel to the top surface of the first substrate. The first protrusion part and the first pillar part may not have a boundary therebetween. The dummy vertical structure may include: a second pillar part that extends in the direction perpendicular to the top surface of the first substrate; and a second protrusion part that protrudes in the first direction from the second pillar part, the second protrusion part and the second pillar part do not have a boundary therebetween. Each of the first and second protrusion parts may have a circular annular shape or a polygonal annular shape when viewed in plan. When viewed in plan, the semiconductor memory device may have a first width that is a distance from a center of the cell contact plug to a center of the dummy vertical structure. The first protrusion part may have a second width that is a maximum diameter of an outer perimeter of the first protrusion part. The semiconductor memory device may have a third width that is a minimum horizontal distance from the first protrusion part to the second protrusion part. The third width may be equal to a difference between the first width and the second width.

According to some embodiments of the present inventive concepts, an electronic system may comprise: a three-dimensional semiconductor memory device that includes a first substrate, a peripheral circuit structure on the first substrate, and a cell array structure on the peripheral circuit structure, the cell array structure including a cell array region and a cell array contact region; and a controller electrically connected through an input/output pad to the three-dimensional semiconductor memory device, the controller controlling the three-dimensional semiconductor memory device. The cell array structure may include: a second substrate; a first stack structure and a second stack structure that are stacked on the second substrate, each of the first and second stack structures including interlayer dielectric layers and gate electrodes that are alternately disposed; a vertical channel structure in the cell array region, the vertical channel structure penetrating at least a portion of the first and second stack structures and a portion of the second substrate; and a cell contact plug in the cell array contact region, the cell contact plug penetrating at least a portion of the first and second stack structures and a portion of the second substrate. The cell contact plug may include: a pillar part that extends in a direction perpendicular to a top surface of the first substrate; and a protrusion part that protrudes from the pillar part in a first direction parallel to the top surface of the first substrate. The protrusion part and the pillar part may be a single unitary piece. A top surface of the protrusion part may be at a same distance as a distance of a top surface of an uppermost one of the interlayer dielectric layers in the first stack structure from the top surface of the first substrate. A bottom surface of the protrusion part may be at a greater distance than a distance of a bottom surface of the uppermost one of the interlayer dielectric layers in the first stack structure from the top surface of the first substrate.

### BRIEF DESCRIPTION OF THE DRAWINGS

FIG. 1 illustrates a simplified schematic diagram showing an electronic system that includes a semiconductor device according to some embodiments of the present inventive concepts.

FIG. 2 illustrates a simplified perspective view showing an electronic system that includes a semiconductor device according to some embodiments of the present inventive concepts.

FIGS. 3 and 4 illustrate simplified cross-sectional views taken along line I-I′ of FIG. 2, showing a semiconductor package according to some embodiments of the present inventive concepts.

FIG. 5 illustrates a plan view showing a three-dimensional semiconductor memory device according to some embodiments of the present inventive concepts.

FIGS. 6A and 6B illustrate cross-sectional views respectively taken along lines A-A′ and B-B′ of FIG. 5, showing a three-dimensional semiconductor memory device according to some embodiments of the present inventive concepts.

FIG. 7A illustrates an enlarged view showing section QQ of FIG. 6A.

FIG. 7B illustrates an enlarged view showing section RR of FIG. 6A.

FIG. 7C illustrates an enlarged view showing section SS of FIG. 6A.

FIG. 7D illustrates an enlarged view showing section TT of FIG. 6B.

FIG. 8 illustrates a cross-sectional view taken along line C-C′ of FIG. 5, showing a three-dimensional semiconductor memory device according to some embodiments of the present inventive concepts.

FIGS. 9, 10, 11, 12, 13, 14, 15, and 16 illustrate cross-sectional views taken along line A-A′ of FIG. 5, showing a method of fabricating a three-dimensional semiconductor memory device according to some embodiments of the present inventive concepts.

FIG. 17 illustrates a cross-sectional view taken along line A-A′ of FIG. 5, showing a three-dimensional semiconductor memory device according to some embodiments of the present inventive concepts.

### DETAILED DESCRIPTION OF EMBODIMENTS

The following will now describe in detail a three-dimensional semiconductor memory device, a method of fabricating the same, and an electronic system including the same according to some embodiments of the present inventive concepts in conjunction with the accompanying drawings.

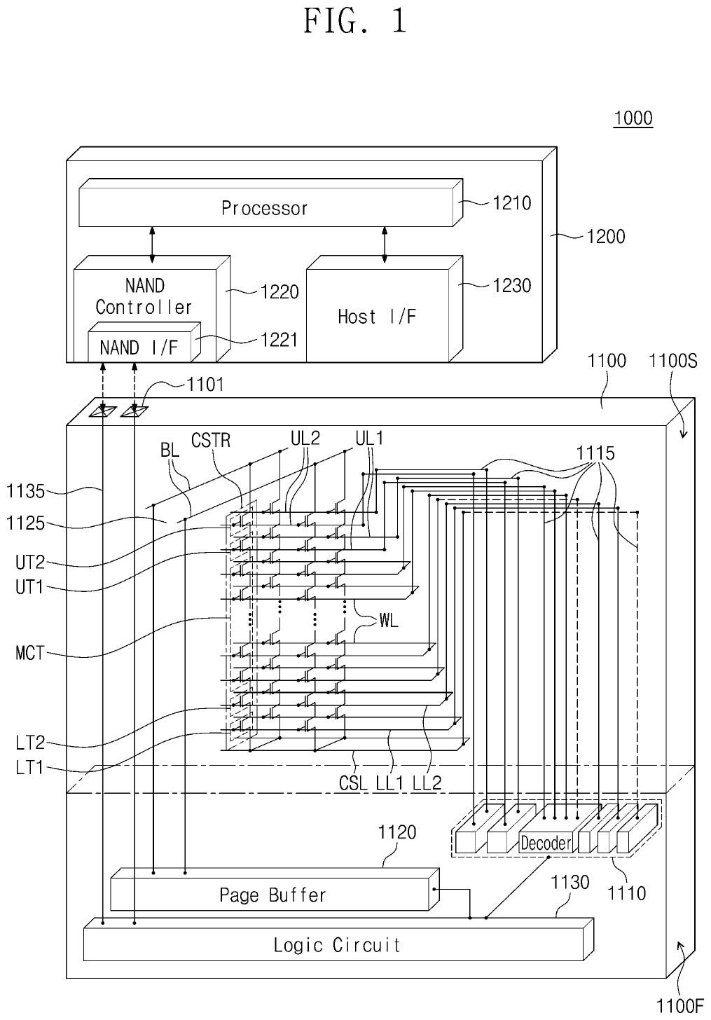

FIG. 1 illustrates a simplified schematic diagram showing an electronic system that includes a semiconductor device according to some embodiments of the present inventive concepts.

Referring to FIG. 1, an electronic system 1000 according to some embodiments of the present inventive concepts may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S. The first structure 1100F may be a peripheral circuit structure. For example, the first structure 1100F may include a decoder circuit 1110, a page buffer 1120, and a logic circuit 1130. The second structure 1100S may be a memory cell structure. For example, the second structure 1100S may include a bit line BL, a common source line CSL, word lines WL, first and second gate upper lines UL1 and UL2, first and second gate lower lines LL1 and LL2, and memory cell strings CSTR between the bit line BL and the common source line CSL. The first and second gate upper lines UL1 and UL2 may be collectively referred to as gate upper lines UL1 and UL2 hereinafter. Likewise, the first and second gate lower lines LL1 and LL2 may be collectively referred to as gate lower lines LL1 and LL2 hereinafter.

For the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the lower transistors LT1 and LT2 may include a lower erase control transistor LT1 and a ground selection transistor LT2 that are electrically connected in series. The upper transistors UT1 and UT2 may include a string selection transistor UT1 and an upper erase control transistor UT2 that are electrically connected in series. One or both of the lower and upper erase control transistors LT1 and UT1 may be employed to perform an erase operation in which a gate induced drain leakage (GIDL) phenomenon is used to erase data stored in the memory cell transistors MCT.

In some embodiments, the first and second gate lower lines LL1 and LL2 may be gate electrodes of the lower erase control transistor LT1 and the ground selection transistor LT2, respectively. The word lines WL may be gate electrodes of the memory cell transistors MCT, and the first and second gate upper lines UL1 and UL2 may be gate electrodes of the string selection transistor UT1 and the upper erase control transistor UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend between (e.g., from) the first structure 1100F and (e.g., toward) the second structure 1100S. The bit lines BL may be electrically connected to the page buffer 1120 through second connection lines 1125 that extend between (e.g., from) the first structure 1100F and (e.g., toward) the second structure 1100S.

For the first structure 1100F, the decoder circuit 1110 and the page buffer 1120 may perform a control operation to at least one selected memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends between (e.g., from) the first structure 1100F and (e.g., toward) the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

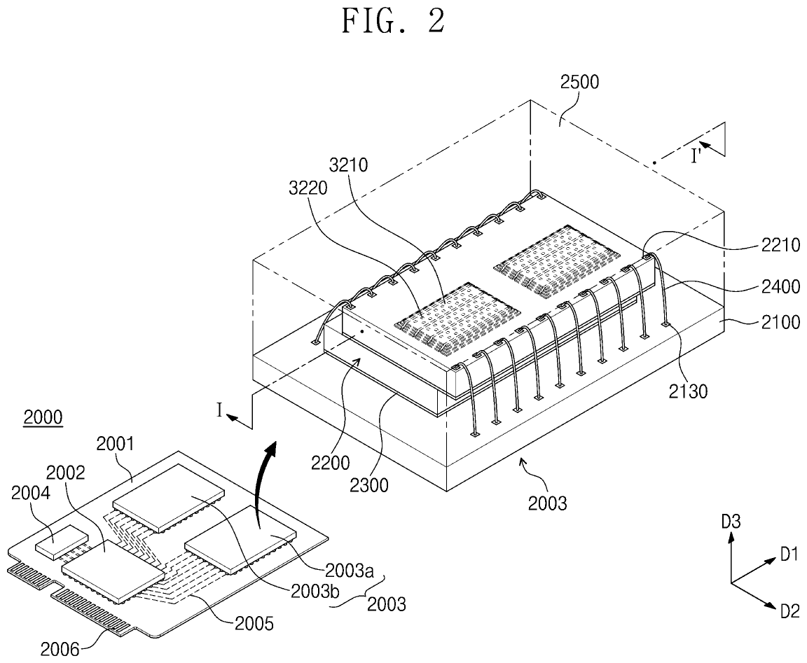

FIG. 2 illustrates a simplified perspective view showing an electronic system that includes a semiconductor device according to some embodiments of the present inventive concepts.

Referring to FIG. 2, an electronic system 2000 according to some embodiments of the present inventive concepts may include a main board 2001, and may also include a controller 2002, at least one semiconductor package 2003, and a dynamic random access memory (DRAM) 2004 that are mounted on the main board 2001. The semiconductor package 2003 and the DRAM 2004 may be connected to the controller 2002 through wiring patterns 2005 formed on the main board 2001.

The main board 2001 may include a connector 2006 including a plurality of pins that are provided to have connection with an external host. The number and arrangement of the plurality of pins on the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may control (e.g., increase or decrease) an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but a DRAM controller for controlling the DRAM 2004.

The semiconductor package 2003 may include first and second semiconductor packages 2003a and 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on (e.g., covers or overlaps) the package substrate 2100, the semiconductor chips 2200, and the connection structures 2400.

The package substrate 2100 may be an integrated circuit board including package upper pads 2130. Each of the semiconductor chips 2200 may include one or more input/output pads 2210. The input/output pad 2210 may correspond to the input/output pad 1101 of FIG. 1. Each of the semiconductor chips 2200 may include electrode structures 3210 and vertical structures 3220. Each of the semiconductor chips 2200 may include a semiconductor device according to some embodiments of the present inventive concepts which will be discussed below.

In some embodiments, the connection structures 2400 may be bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b, the semiconductor chips 2200 may be electrically connected to each other through connection structures such as through silicon vias (TSV) instead of the connection structures 2400 shaped like bonding wires.

In some embodiments, the controller 2002 and the semiconductor chips 2200 may be included in a single package. For example, the controller 2002 and the semiconductor chips 2200 may be mounted on an interposer substrate other than the main board 2001, and may be connected to each other through wiring lines formed on the interposer substrate.

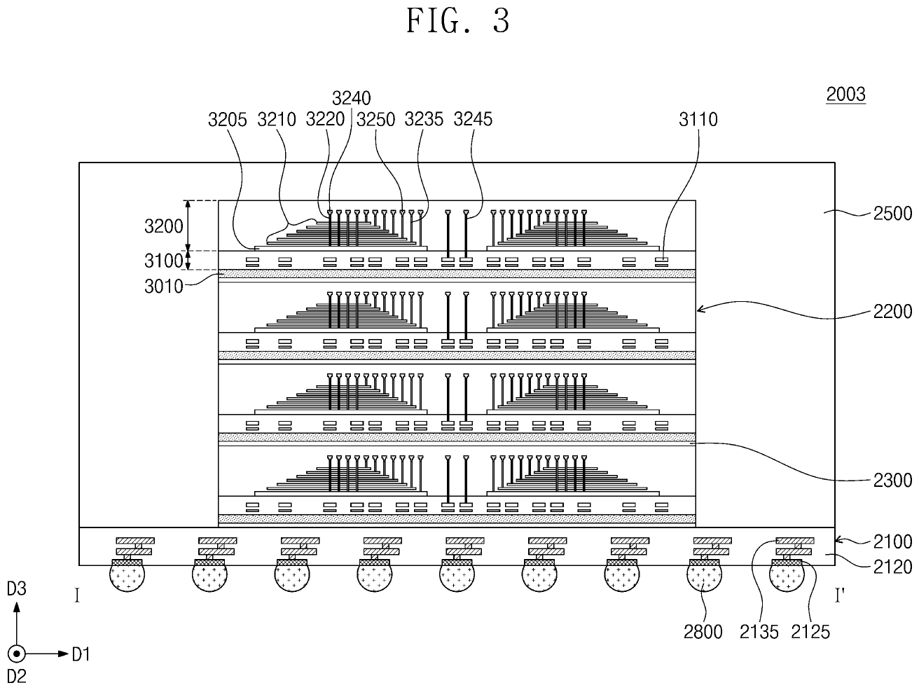

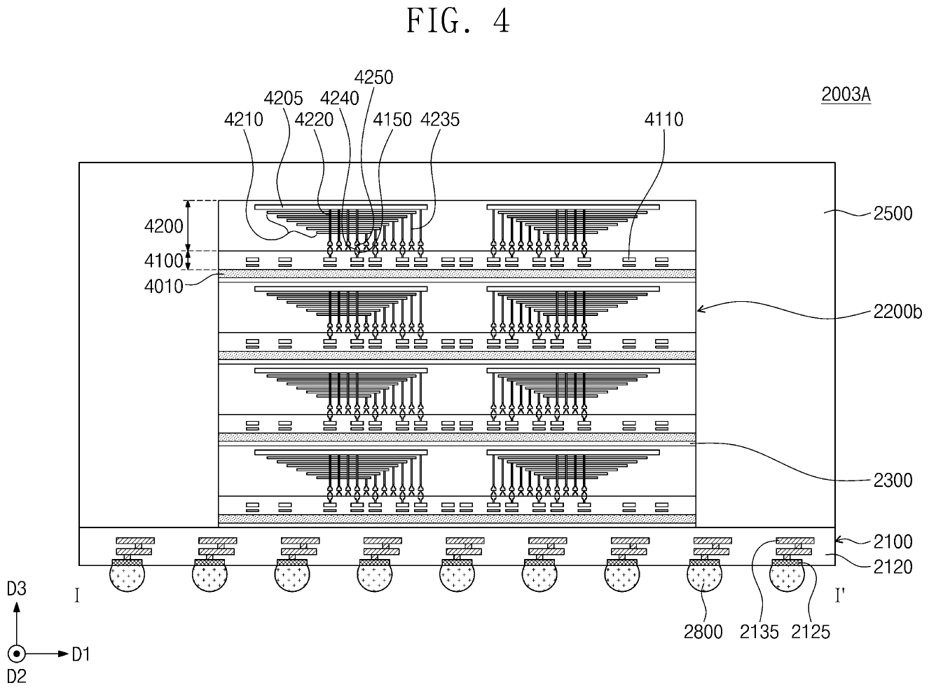

FIGS. 3 and 4 illustrate simplified cross-sectional views taken along line I-I′ of FIG. 2, showing a semiconductor package according to some embodiments of the present inventive concepts. FIGS. 3 and 4 each depicts an example of the semiconductor package 2003 illustrated in FIG. 2, conceptually showing a section taken along line I-I′ of the semiconductor package 2003 illustrated in FIG. 2.

Referring to FIGS. 2 and 3, a printed circuit board may be used as the package substrate 2100 of the semiconductor package 2003. The package substrate 2100 may include a package substrate body 2120, package upper pads 2130 disposed on a top surface of the package substrate body 2120, package lower pads 2125 disposed or exposed on a bottom surface of the package substrate body 2120, and internal wiring lines 2135 through which the package upper pads 2130 and the package lower pads 2125 are electrically connected to each other in the package substrate body 2120. The package upper pads 2130 may be electrically connected to the connection structures 2400. The package lower pads 2125 may be connected through conductive connectors 2800 to the wiring patterns 2005 in the main board 2001 of the electronic system 2000 as shown in FIG. 2.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a source structure 3205, an electrode structure 3210 on the source structure 3205, vertical structures 3220 and separation structures that penetrate the electrode structure 3210, bit lines 3240 (corresponding to BL of FIG. 1) electrically connected to the vertical structures 3220, and cell contact plugs 3235 electrically connected to word lines 3250 (corresponding to WL of FIG. 1) of the electrode structure 3210. One or more of the first structure 3100, the second structure 3200, and the semiconductor chips 2200 may further a metal structure which will be discussed below.

Each of the semiconductor chips 2200 may include one or more through wiring lines 3245 that extend into the second structure 3200 and are electrically connected to the peripheral wiring lines 3110 of the first structure 3100. The through wiring lines 3245 may be disposed outside the electrode structure 3210 and may further be disposed to penetrate the electrode structure 3210. Each of the semiconductor chips 2200 may further include one or more input/output pads (see 2210 of FIG. 2) electrically connected to the peripheral wiring lines 3110 of the first structure 3100.

Referring to FIG. 4, a semiconductor package 2003A may be configured such that each of semiconductor chips 2200b may include a semiconductor substrate 4010, a first structure 4100 on the semiconductor substrate 4010, and a second structure 4200 to which the first structure 4100 may be bonded in a wafer bonding manner on the first structure 4100.

The first structure 4100 may include a peripheral circuit region including peripheral wiring lines 4110 and first bonding structures 4150. The second structure 4200 may include a source structure 4205, an electrode structure 4210 between the source structure 4205 and the first structure 4100, vertical structures 4220 and separation structures that penetrate the electrode structure 4210, and second bonding structures 4250 that are correspondingly electrically connected to the vertical structures 4220 and word lines (see WL of FIG. 1) of the electrode structure 4210. For example, the second bonding structures 4250 may be electrically connected to the vertical structures 4220 through bit lines 4240 electrically connected to the vertical structures 4220, and may also be electrically connected to the word lines (see WL of FIG. 1) through cell contact plugs 4235 electrically connected to the word lines (see WL of FIG. 1). The first bonding structures 4150 of the first structure 4100 and the second bonding structures 4250 of the second structure 4200 may be bonded to each other while being in contact with each other. The first and second bonding structures 4150 and 4250 may have their bonding portions formed of, for example, copper (Cu).

One or more of the first structure 4100, the second structure 4200, and the semiconductor chips 2200b may further include a metal structure which will be discussed in the following embodiments. Each of the semiconductor chips 2200b may further include one or more input/output pads (see 2210 of FIG. 2) electrically connected to the peripheral wiring lines 4110.

The semiconductor chips 2200 of FIG. 3 or the semiconductor chips 2200b of FIG. 4 may be electrically connected to each other through the connection structures 2400 shaped like bonding wires (see 2400 in FIG. 2). In some embodiments, semiconductor chips, such as the semiconductor chips 2200 of FIG. 3 or the semiconductor chips 2200b of FIG. 4, in a single semiconductor package may be electrically connected to each other through one or more connection structures that include through electrodes such as TSV (through silicon via).

The first structure 3100 of FIG. 3 and the first structure 4100 of FIG. 4 may correspond to a peripheral circuit structure which will be discussed in the following embodiments, and the second structure 3200 of FIG. 3 and the second structure 4200 of FIG. 4 may correspond to a cell array structure which will be discussed in the following embodiments.

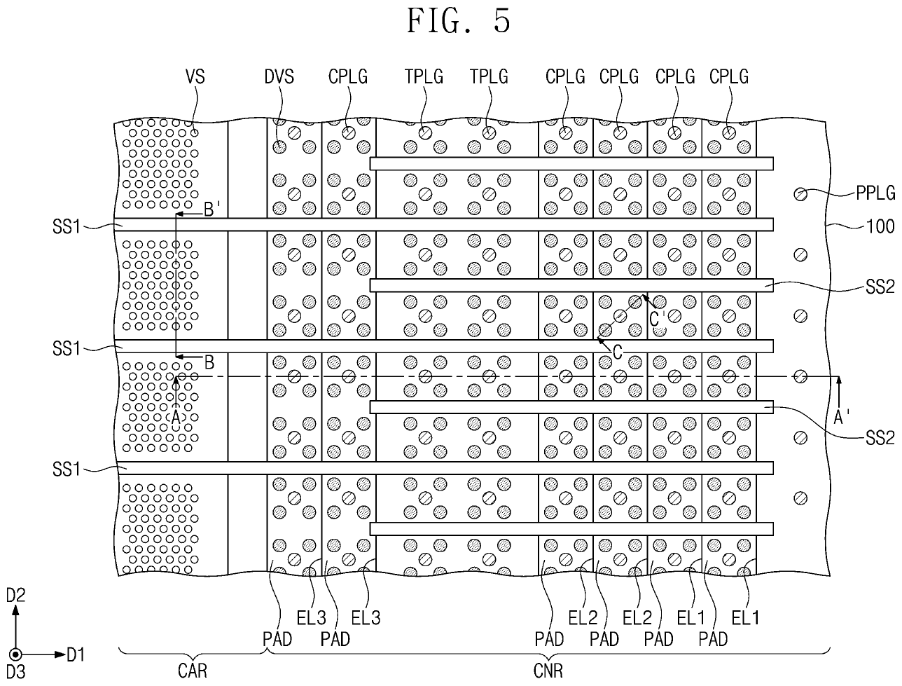

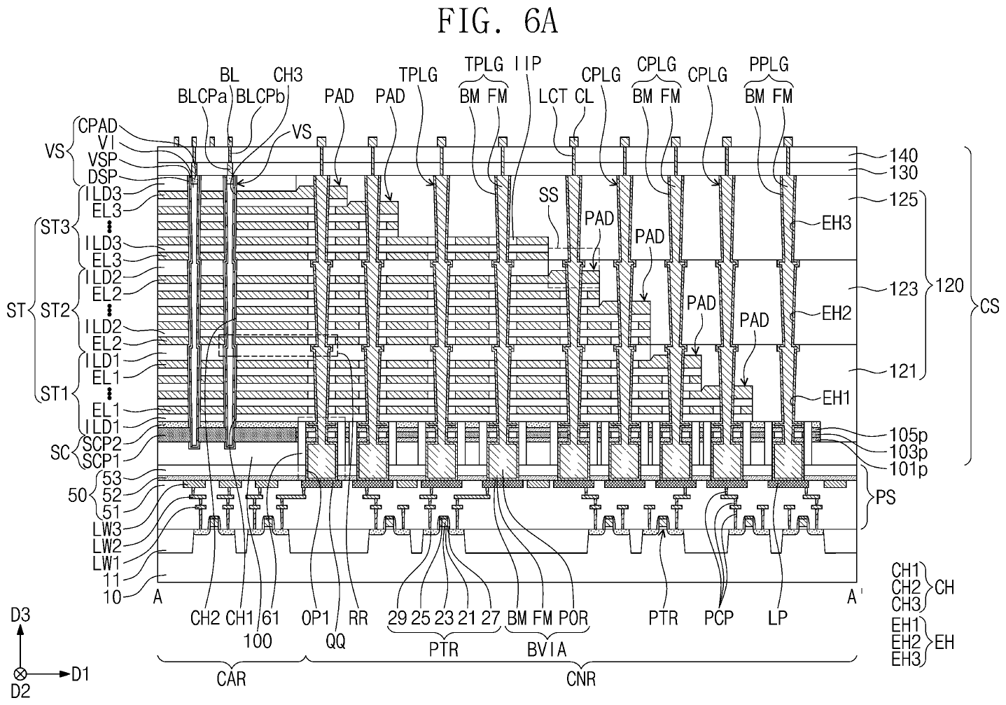

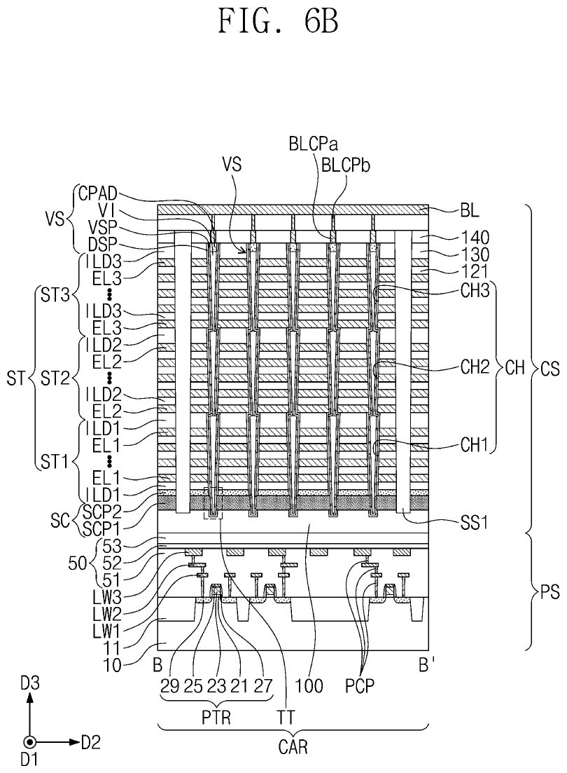

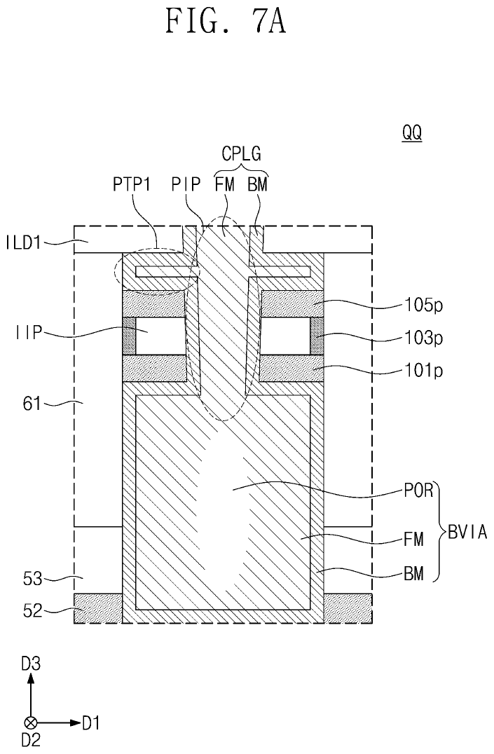

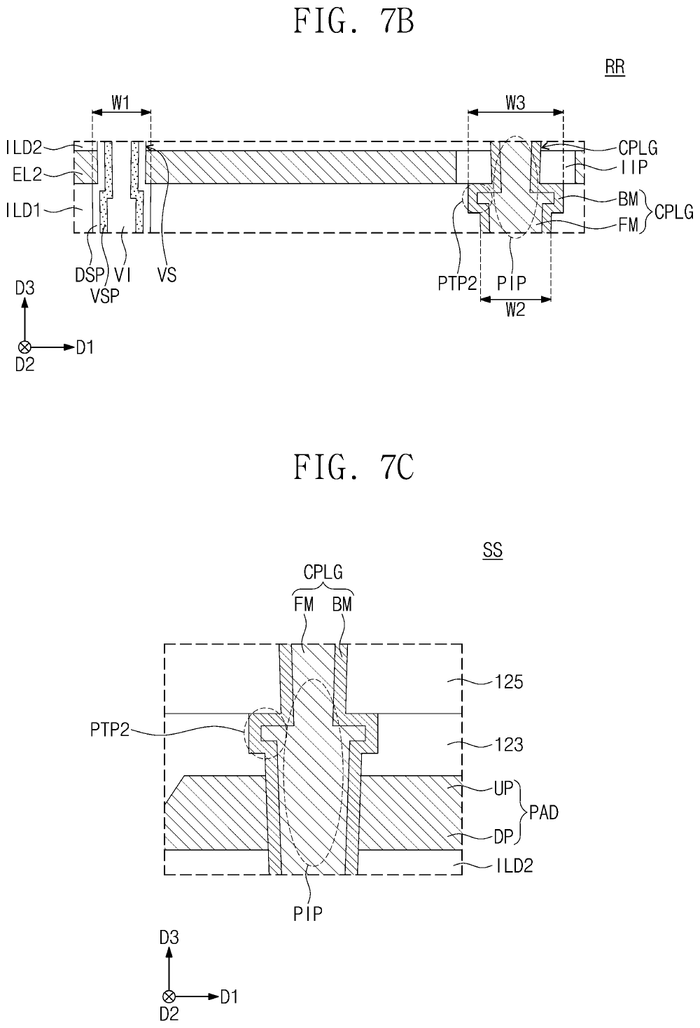

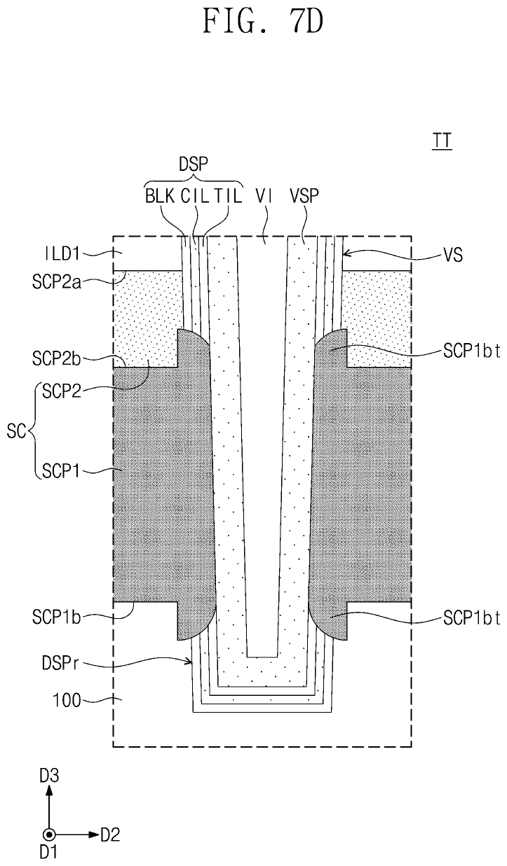

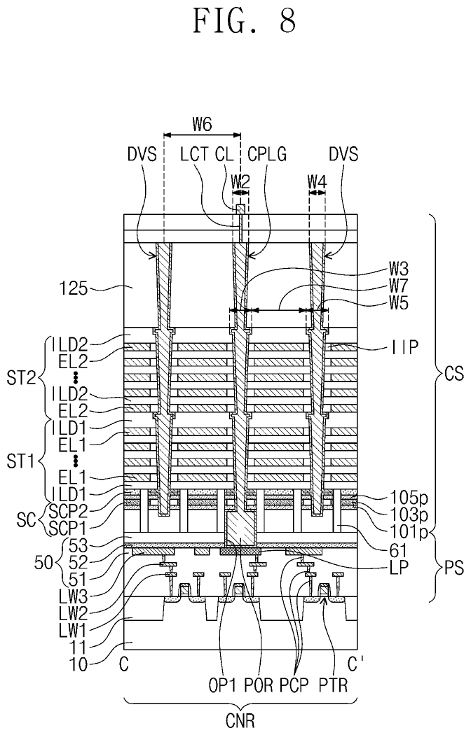

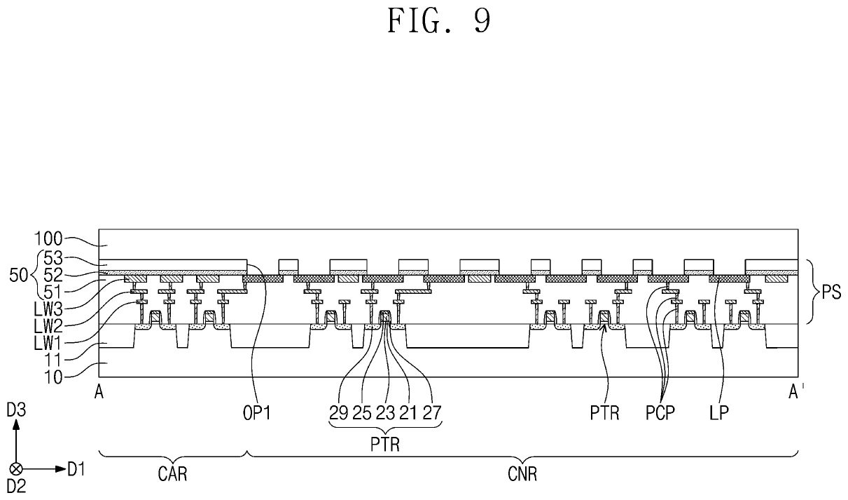

FIG. 5 illustrates a plan view showing a three-dimensional semiconductor memory device according to some embodiments of the present inventive concepts. FIGS. 6A and 6B illustrate cross-sectional views respectively taken along lines A-A′ and B-B′ of FIG. 5, showing a three-dimensional semiconductor memory device according to some embodiments of the present inventive concepts. FIG. 7A illustrates an enlarged view showing section QQ of FIG. 6A. FIG. 7B illustrates an enlarged view showing section RR of FIG. 6A. FIG. 7C illustrates an enlarged view showing section SS of FIG. 6A. FIG. 7D illustrates an enlarged view showing section TT of FIG. 6B. FIG. 8 illustrates a cross-sectional view taken along line C-C′ of FIG. 5, showing a three-dimensional semiconductor memory device according to some embodiments of the present inventive concepts.

Referring to FIGS. 5, 6A, and 6B, a three-dimensional semiconductor memory device according to some embodiments of the present inventive concepts may include a first substrate 10, a peripheral circuit structure PS on the first substrate 10, and a cell array structure CS on the peripheral circuit structure PS. The first substrate 10, the peripheral circuit structure PS, and the cell array structure CS may respectively correspond to the semiconductor substrate 3010, the first structure 3100 on the semiconductor substrate 3010, and the second structure 3200 on the first structure 3100 of FIG. 3.

The first substrate 10 may be, for example, a silicon substrate, a silicon-germanium substrate, a germanium substrate, or a monocrystalline epitaxial layer grown on a monocrystalline silicon substrate. The first substrate 10 may have a top surface that is parallel to a first direction D1 and a second direction D2 that intersects the first direction D1 and is perpendicular to a third direction D3. The first, second, and third directions D1, D2, and D3 may be directions orthogonal to each other. A device isolation layer 11 may be provided in the first substrate 10. The device isolation layer 11 may define an active region of the first substrate 10. The device isolation layer 11 may include a dielectric material, such as silicon oxide.

The first substrate 10 may be provided thereon with the peripheral circuit structure PS that includes peripheral transistors PTR, peripheral contact plugs PCP, first to third lower wiring lines LW1, LW2, and LW3 and landing pads LP electrically connected through the peripheral contact plugs PCP to the peripheral transistors PTR, and lower dielectric layers 50 on (e.g., that covers) the peripheral transistors PTR, the peripheral contact plugs PCP, the lower wiring lines LW1, LW2, and LW3, and the landing pads LP.

The peripheral transistors PTR may be provided on the active region of the first substrate 10. The peripheral transistors PTR may constitute, for example, a decoder circuit (see 1110 of FIG. 1), a page buffer (see 1120 of FIG. 1), and a logic circuit (see 1130 of FIG. 1). For example, each of the peripheral transistors PTR may include a peripheral gate dielectric layer 21, a peripheral gate electrode 23, a peripheral capping pattern 25, a peripheral gate spacer 27, and peripheral source/drain regions 29. The peripheral gate dielectric layer 21 may be provided between the peripheral gate electrode 23 and first substrate 10. The peripheral capping pattern 25 may be provided on the peripheral gate electrode 23. The peripheral gate spacer 27 may be on (e.g., cover) a sidewall of each of the peripheral gate dielectric layer 21, the peripheral gate electrode 23, and/or the peripheral capping pattern 25. The peripheral source/drain regions 29 may be provided in the first substrate 10 adjacent to opposite sides of the peripheral gate electrode 23. Each of the peripheral transistors PTR may be, for example, an NMOS transistor or a PMOS transistor.

The peripheral contact plugs PCP may connect the peripheral transistors PTR to the lower wiring lines LW1, LW2, and LW3. The peripheral contact plugs PCP may connect the peripheral transistors PTR to the landing pads LP. The peripheral contact plugs PCP may each have a width in the first direction D1 or the second direction D2, and for example, the width may change (e.g., increase) with increased distance from the top surface of the first substrate 10 in the third direction D3. The peripheral contact plugs PCP, the lower wiring lines LW1, LW2, and LW3, and the landing pads LP may include a conductive material, such as metal.

The lower wiring lines LW1, LW2, and LW3 may be disposed on the first substrate 10. The lower wiring lines LW1, LW2, and LW3 may correspond to the peripheral wiring lines 3110 of FIG. 3.

The lower wiring lines LW1, LW2, and LW3 may be (e.g., electrically) connected through the peripheral contact plugs PCP to the peripheral transistors PTR. For example, the lower wiring lines LW1, LW2, and LW3 may be electrically connected to corresponding ones of the peripheral gate electrodes 23 and the peripheral source/drain regions 29 of the peripheral transistors PTR. The lower wiring lines LW1, LW2, and LW3 may include first lower wiring lines LW1, second lower wiring lines LW2, and third lower wiring lines LW3 that are distinguished based on vertical levels. The first lower wiring lines LW1 may be positioned closer than the third lower wiring lines LW3 to the top surface of the first substrate 10. The second lower wiring lines LW2 may be located at a vertical level between that of the first lower wiring lines LW1 and that of the third lower wiring lines LW3. The lower wiring lines LW1, LW2, and LW3 may be (e.g., electrically) connected to each other through the peripheral contact plugs PCP.

The landing pads LP (e.g., electrically) connected to the peripheral transistors PTR may be provided in a cell array contact region CNR. In some embodiments, the landing pads LP may be located at the same vertical level as that of the third lower wiring lines LW3. For example, the landing pads LP may have top and bottom surfaces located at their levels the same as those of top and bottom surfaces of the third lower wiring lines LW3.

In some embodiments, the landing pads LP may vertically overlap the first lower wiring lines LW1 and the second lower wiring lines LW2. The landing pads LP may be coupled and/or (electrically) connected to the peripheral source/drain regions 29 through the first lower wiring lines LW1, the second lower wiring lines LW2, and the peripheral contact plugs PCP. The landing pads LP may include, for example, aluminum, copper, and/or tungsten.

A lower dielectric layer 50 may be provided on the first substrate 10. On the first substrate 10, the lower dielectric layer 50 may cover the peripheral transistors PTR, the peripheral contact plugs PCP, and the lower wiring lines LW1, LW2, and LW3. The peripheral contact plugs PCP and the lower wiring lines LW1, LW2, and LW3 (e.g., peripheral wiring lines 3110 of FIG. 3) may be electrically connected to the peripheral transistors PTR.

The lower dielectric layer 50 may include a plurality of stacked dielectric layers. For example, the lower dielectric layer 50 may include one or more of a silicon oxide layer, a silicon nitride layer, a silicon oxynitride layer, and a low-k dielectric layer. The lower dielectric layer 50 may include a first lower dielectric layer 51, a second lower dielectric layer 53, and an etch stop layer 52 between the first and second lower dielectric layers 51 and 53. The etch stop layer 52 may include a dielectric material different from those of the first and second lower dielectric layers 51 and 53, and may cover the top surfaces of the third lower wiring lines LW3 and the top surfaces of the landing pads LP. The etch stop layer 52 and the second lower dielectric layer 53 may have first openings OP1. Each of the first openings OP1 may have a circular or polygonal shape when viewed in plan.

The cell array structure CS may be disposed on the lower dielectric layer 50. The cell array structure CS may include a second substrate 100, a source structure SC, a stack structure ST, vertical channel structures VS, cell contact plugs CPLG, through contact plugs TPLG, peripheral contact plugs PPLG, dummy vertical structures DVS, bit lines BL, and conductive lines CL.

According to some embodiments, the memory cell strings CSTR in FIG. 1 may be integrated on the second substrate 100. The stack structure ST and the vertical channel structures VS may constitute the memory cell strings CSTR in FIG. 1.

For example, the second substrate 100 may be disposed on a top surface of the lower dielectric layer 50. The second substrate 100 may be formed of a semiconductor material, a dielectric material, and/or a conductive material. The second substrate 100 may include a semiconductor doped with impurities having a first conductivity type (e.g., n-type) or an intrinsic semiconductor with no impurities doped. The second substrate 100 may include a monocrystalline structure, an amorphous structure, and/or a polycrystalline structure.

The source structure SC may be disposed between the second substrate 100 and the stack structure ST. The source structure SC may be parallel to a top surface of the second substrate 100, and in a cell array region CAR, may extend in the first direction D1 parallel to the stack structure ST.

The source structure SC may include a first source conductive pattern SCP1 and a second source conductive pattern SCP2 on the first source conductive pattern SCP1. In the cell array region CAR, the first source conductive pattern SCP1 may be disposed between the second substrate 100 and the stack structure ST. The first source conductive pattern SCP1 may be, for example, formed of a semiconductor material doped with first conductivity impurities (e.g., phosphorus (P) or arsenic (As)). For example, the first source conductive pattern SCP1 may be formed of a polysilicon layer doped with n-type impurities.

According to some embodiments, in the cell array contact region CNR, a dummy dielectric pattern 101p, 103p, and 105p may be disposed between the second substrate 100 and the stack structure ST. The dummy dielectric pattern 101p, 103p, and 105p may have top and bottom surfaces located at their levels the same as those of top and bottom surfaces of the first source conductive pattern SCP1.

The dummy dielectric pattern 101p, 103p, and 105p may include first, second, and third dummy dielectric patterns 101p, 103p, and 105p that are sequentially stacked. The second dummy dielectric pattern 103p may include a dielectric material different from those of the first and third dummy dielectric patterns 101p and 105p. The second dummy dielectric pattern 103p may be thicker than the first and third dummy dielectric patterns 101p and 105p. Each of the first, second, and third dummy dielectric patterns 101p, 103p, and 105p may be, for example, a silicon oxide layer, a silicon nitride layer, a silicon oxynitride layer, a silicon carbide layer, and/or a silicon-germanium layer.

The second source conductive pattern SCP2 may extend from the cell array region CAR to the cell array contact region CNR. The second source conductive pattern SCP2 may cover the top surface of the first source conductive pattern SCP1 in the cell array region CAR, and may cover the top surfaces of the dummy dielectric pattern 101p, 103p, and 105p in the cell array contact region CNR. The second source conductive pattern SCP2 may include, for example, a semiconductor doped with impurities having the first conductivity type (e.g., n-type) or an intrinsic semiconductor with no impurities doped.

Although not shown, in the cell array region CAR, portions of the second source conductive pattern SCP2 may penetrate the first source conductive pattern SCP1 to come into contact with the second substrate 100. In the cell array contact region CNR, portions of the second source conductive pattern SCP2 may penetrate the dummy dielectric pattern 101p, 103p, and 105p to come into contact with the second substrate 100.

The stack structure ST may be disposed on the source structure SC. The stack structure ST may extend from the cell array region CAR toward the cell array contact region CNR along the first direction D1, and may have a stepwise structure in the cell array contact region CNR.

The stack structure ST may be provided in plural. When viewed in plan as shown in FIG. 5, the plurality of stack structures ST may extend in the first direction D1 and may be spaced apart from each other in the second direction D2. For convenience of description, the following will explain a single stack structure ST, and the explanation may be identically applicable to other stack structures ST.

The stack structure ST may include gate electrodes EL1, EL2, and EL3 and interlayer dielectric layers ILD1, ILD2, and ILD3 that are alternately stacked along the third direction D3. The gate electrodes EL1, EL2, and EL3 may comprise first gate electrodes EL1, second gate electrodes EL2, and third gate electrodes EL3. The interlayer dielectric layers ILD1, ILD2, and ILD3 may comprise first interlayer dielectric layers ILD1, second interlayer dielectric layers ILD2, and third interlayer dielectric layers ILD3. The number of gate electrodes and interlayer dielectric layers (e.g., three of each) is an example embodiment, and the present inventive concepts are not limited thereto. The gate electrodes EL1, EL2, and EL3 may include, for example, doped semiconductors (e.g., doped silicon), metals (e.g., tungsten, copper, or aluminum), conductive metal nitrides (e.g., titanium nitride or tantalum nitride), and/or transition metals (e.g., titanium or tantalum). The interlayer dielectric layers ILD1, ILD2, and ILD3 may include, for example, one or more of a silicon oxide layer and/or a low-k dielectric layer. According to some embodiments, the semiconductor device may be a vertical NAND Flash memory device, and in this case, the gate electrodes EL1, EL2, and EL3 of the stack structure ST may be used as the gate lower lines LL1 and LL2, the word lines WL, and the gate upper lines UL1 and UL2 discussed with reference to FIG. 1.

According to some embodiments, the stack structure ST may include a first stack structure ST1, a second stack structure ST2, and a third stack structure ST3 that are sequentially stacked. The first stack structure ST1 may include first gate electrodes EL1 and first interlayer dielectric layers ILD1 that are alternately stacked in the third direction D3 on the second substrate 100. The second stack structure ST2 may include second gate electrodes EL2 and second interlayer dielectric layers ILD2 that are alternately stacked in the third direction D3 on the first stack structure ST1. The third stack structure ST3 may include third gate electrodes EL3 and third interlayer dielectric layers ILD3 that are alternately stacked in the third direction D3 on the second stack structure ST2.

An uppermost first interlayer dielectric layer ILD1 may have a thickness greater than that of each of other first interlayer dielectric layers ILD1. An uppermost second interlayer dielectric layer ILD2 may have a thickness greater than that of each of other second interlayer dielectric layers ILD2. An uppermost third interlayer dielectric layer ILD3 may have a thickness greater than that of each of other third interlayer dielectric layers ILD3. This configuration is merely an embodiment, and the present inventive concepts are not limited thereto.

In the cell array contact region CNR, each of the first, second, and third stack structures ST1, ST2, and ST3 may have a thickness in the third direction D3 that decreases with increasing distance from an outermost one of the vertical channel structures VS which will be discussed below. For example, each of the first, second, and third stack structures ST1, ST2, and ST3 may have a stepwise structure along the first direction D1.

The first gate electrodes EL1, the second gate electrodes EL2, and the third gate electrodes EL3 may have their lengths in the first direction D1 that decrease with increasing distance from the second substrate 100. The first, second, and third gate electrodes EL1, EL2, and EL3 may have their sidewalls that are spaced apart from each other at a certain interval along the first direction D1. According to some embodiments, a distance between neighboring ones among the sidewalls of the first, second, and third gate electrodes EL1, EL2, and EL3 may be greater than distances between other sidewalls of the sidewalls of the first, second, and third gate electrodes EL1, EL2, and EL3. This configuration may be changed in accordance with design of the three-dimensional semiconductor memory device which is intended to be implemented.

A lowermost one of the first gate electrodes EL1 in the first stack structure ST1 may have a length in the first direction D1 greater than any other of the first gate electrodes EL1 in the first stack structure ST1. A lowermost one of the second gate electrodes EL2 in the second stack structure ST2 may have a length in the first direction D1 greater than any other of the second gate electrodes EL2 in the second stack structure ST2. A lowermost one of the third gate electrodes EL3 in the third stack structure ST3 may have a length in the first direction D1 greater than any other of the third gate electrodes EL3 in the third stack structure ST3.

The first, second, and third gate electrodes EL1, EL2, and EL3 may have their pad parts PAD in the cell array contact region CNR. The pad parts PAD may be disposed at positions that are horizontally and vertically different from each other. The pad parts PAD may constitute a stepwise structure along the first direction D1 or the second direction D2. Each of the pad parts PAD may protrude in the third direction D3, or a direction away from the second substrate 100. For example, on each of the gate electrodes EL1, EL2, and EL3, each of the pad parts PAD may have a thickness greater than that of another part other than the pad part PAD.

The first, second, and third interlayer dielectric layers ILD1, ILD2, and ILD3 may be provided between the first, second, and third gate electrodes EL1, EL2, and EL3, and each of the first, second, and third interlayer dielectric layers ILD1, ILD2, and ILD3 may have a sidewall aligned with that of one of the first, second, and third gate electrodes EL1, EL2, and EL3 that is upwardly in contact therewith.

A planarized dielectric layer 120 may be provided to cover the stepwise structure of the stack structure ST. The planarized dielectric layer 120 may include a first planarized dielectric layer 121, a second planarized dielectric layer 123, and a third planarized dielectric layer 125 that are sequentially stacked on the second substrate 100. The number of the planarized dielectric layer (e.g., three) is an example, and the present inventive concepts are not limited thereto

The first planarized dielectric layer 121 may cover the second substrate 100, the dummy dielectric pattern 101p, 103p, and 105p, and the pad parts PAD of the first stack structure ST1. The first stack structure ST1 may be surrounded by the first planarized dielectric layer 121. A top surface of the first planarized dielectric layer 121 may be substantially coplanar with that of the first stack structure ST1.

The second planarized dielectric layer 123 may cover the first planarized dielectric layer 121 and the pad parts PAD of the second stack structure ST2. The second stack structure ST2 may be surrounded by the second planarized dielectric layer 123. A top surface of the second planarized dielectric layer 123 may be substantially coplanar with that of the second stack structure ST2.

The third planarized dielectric layer 125 may cover the second planarized dielectric layer 123 and the pad parts PAD of the third stack structure ST3. The third stack structure ST3 may be surrounded by the third planarized dielectric layer 125. A top surface of the third planarized dielectric layer 125 may be substantially coplanar with that of the third stack structure ST3.

The first, second, and third planarized dielectric layers 121, 123, and 125 may include, for example, a silicon oxide layer and/or a low-k dielectric layer.

First separation structures SS1 and second separation structures SS2 may penetrate the stack structure ST on the second substrate 100. Each of the first and second separation structures SS1 and SS2 may include a dielectric layer that covers a sidewall of the stack structure ST. Each of the first and second separation structures SS1 and SS2 may have a single-layered or multi-layered structure formed of a dielectric material. The first and second separation structures SS1 and SS2 may have their top surfaces located at substantially the same level.

The first separation structures SS1 may extend along the first direction D1 from the cell array region CAR toward the cell array contact region CNR, and may be disposed spaced apart from each other in the second direction D2. The first separation structures SS1 may be in contact with the second substrate 100 in the cell array region CAR.

The second separation structures SS2 may penetrate the planarized dielectric layer 120, the stack structure ST, and the dummy dielectric pattern 101p, 103p, and 105p, while being spaced apart from the first separation structures SS1 in the cell array contact region CNR. The second separation structures SS2 may be in contact with the second substrate 100 in the cell array contact region CNR. The second separation structures SS2 may extend along the first direction D1. A length in the first direction D1 of the second separation structures SS2 may be less than a length in the first direction D1 of the first separation structures SS1. The second separation structures SS2 may be spaced apart from each other in the second direction D2.

In the cell array region CAR, vertical channel structures VS may be provided in vertical channel holes CH that penetrate in the third direction D3 through the stack structure ST and the source structure SC. The vertical channel holes CH may include first vertical channel holes CH1 that penetrate the first stack structure ST1, second vertical channel holes CH2 that are (e.g., electrically) connected to the first vertical channel holes CH1 and penetrate the second stack structure ST2, and third vertical channel holes CH3 that are (e.g., electrically) connected to the second vertical channel holes CH2 and penetrate the third stack structure ST3. Each of the first, second, and third vertical channel holes CH1, CH2, and CH3 may have a width in the first direction D1 or the second direction D2, and the width may increases with increasing distance from the first substrate 10. The first, second, and third vertical channel holes CH1, CH2, and CH3 may have diameters that are different from each other at boundaries where the first, second, and third vertical channel holes CH1, CH2, and CH3 are (e.g., electrically) connected to each other. For example, a lower diameter of each of the second vertical channel holes CH2 may be less than an upper diameter of each of the first vertical channel holes CH1. A lower diameter of each of the third vertical channel holes CH3 may be less than an upper diameter of each of the second vertical channel holes CH2. The first, second, and third vertical channel holes CH1, CH2, and CH3 may have step differences at the boundaries therebetween. The present inventive concepts, however, are not limited thereto, and differently from that shown, each of the vertical structures VS may be provided in three or more vertical channels that have a step difference at each of two or more boundaries therebetween, and one of the vertical structures VS may be provided in one vertical channel that has a flat sidewall with no step difference.

Each of the vertical channel structures VS may penetrate a portion of the second substrate 100 to be inserted into the second substrate 100. When viewed in plan, the vertical channel structures VS may be arranged in a straight or zigzag fashion. The vertical channel structures VS may correspond to the vertical structures 3220 of FIG. 3.

Referring to FIGS. 6A, 6B, and 7D, each of the vertical channel structures VS may include a data storage pattern DSP and a vertical semiconductor pattern VSP that are sequentially provided on an inner wall of the vertical channel hole CH, a buried dielectric pattern VI that fills an internal space surrounded by the vertical semiconductor pattern VSP, and a conductive pad CPAD on the buried dielectric pattern VI. The conductive pad CPAD may be provided in a space surrounded by the buried dielectric pattern VI and the data storage pattern DSP (and/or the vertical semiconductor pattern VSP). The vertical channel structures VS may each have a top surface that has, for example, a circular shape, an oval shape, or a bar shape. The data storage pattern DSP may be adjacent to the stack structure ST to cover sidewalls of the first, second, and third interlayer dielectric layers ILD1, ILD2, and ILD3 and sidewalls of the first, second, and third gate electrodes EL1, EL2, and EL3. The vertical semiconductor pattern VSP may conformally cover an inner wall of the data storage pattern DSP.

The data storage pattern DSP may be provided between the vertical semiconductor pattern VSP and the first, second, and third gate electrodes EL1, EL2, and EL3. The vertical semiconductor pattern VSP may be provided between the data storage pattern DSP and the buried dielectric pattern VI. The vertical semiconductor pattern VSP may have a macaroni shape or a pipe shape whose bottom end is closed. The data storage pattern DSP may have a macaroni shape or a pipe shape whose bottom end is opened.

The data storage pattern DSP may include a blocking dielectric layer BLK, a charge storage layer CIL, and a tunneling dielectric layer TIL that are sequentially stacked. The blocking dielectric layer BLK may be adjacent to the stack structure ST or the source structure SC, and the tunneling dielectric layer TIL may be adjacent to the vertical semiconductor pattern VSP. The charge storage layer CIL may be interposed between the blocking dielectric layer BLK and the tunneling dielectric layer TIL. The blocking dielectric layer BLK may cover the inner wall of the vertical channel hole CH. The charge storage layer CIL may cover an inner wall of the blocking dielectric layer BLK. The tunneling dielectric layer TIL may cover an inner wall of the charge storage layer CIL.

The vertical semiconductor pattern VSP may include, for example, an impurity-doped semiconductor material, an impurity-undoped intrinsic semiconductor material, or a polycrystalline semiconductor material. As discussed below with reference to FIG. 7B, the vertical semiconductor pattern VSP may be in contact with a portion of the source structure SC. The conductive pad CPAD may include, for example, an impurity-doped semiconductor material and/or a conductive material.

The blocking dielectric layer BLK, the charge storage layer CIL, and the tunneling dielectric layer TIL may extend in the third direction D3 between the vertical semiconductor pattern VSP and the gate electrodes EL1, EL2, and EL3. The data storage pattern DSP may store and/or change data, for example, by using Fowler-Nordheim tunneling induced by a voltage difference between the vertical semiconductor pattern VSP and the first, second, and third gate electrodes EL1, EL2, and EL3. For example, the blocking dielectric layer BLK and the tunneling dielectric layer TIL may include silicon oxide, and the charge storage layer CIL may include silicon nitride or silicon oxynitride.

The first source conductive pattern SCP1 of the source structure SC may be electrically connected to (e.g., in contact with) the vertical semiconductor pattern VSP, and the second source conductive pattern SCP2 of the source structure SC may be spaced apart from the vertical semiconductor pattern VSP across the data storage pattern DSP. The first source conductive pattern SCP1 may be spaced apart from the buried dielectric pattern VI across the vertical semiconductor pattern VSP.

For example, the first source conductive pattern SCP1 may include protrusion parts SCP1bt located at a level higher than that of a bottom surface SCP2b of the second source conductive pattern SCP2 or lower than that of a bottom surface SCP1b of the first source conductive pattern SCP1. The protrusion parts SCP1bt may be located at a level lower than that of a top surface SCP2a of the second source conductive pattern SCP2. The protrusion parts SCP1bt may each have, for example, a curved shape at a surface in contact with the data storage pattern DSP and/or a lower data storage pattern DSPr. The lower data storage pattern DSPr may be separated from the data storage pattern DSP by the first source conductive pattern SCP1 (including the protrusion parts SCP1bt) and disposed between the second substrate 100 and the vertical semiconductor pattern VSP.

Referring to FIGS. 5, 6A, 6B, and 8, in the cell array contact region CNR, the cell contact plugs CPLG, the through contact plugs TPLG, the peripheral contact plugs PPLG, and the dummy vertical structures DVS may be provided in connection vertical holes EH that penetrate in the third direction D3 through at least a portion of the stack structure ST and/or at least a portion of the planarized dielectric layer 120. The connection vertical holes EH may include first connection vertical holes EH1 that penetrate one or both of the first stack structure ST1 and the first planarized dielectric layer 121, second connection vertical holes EH2 that are (e.g., electrically) (e.g., electrically) connected to the first connection vertical holes EH1 and penetrate one or both of the second stack structure ST2 and the second planarized dielectric layer 123, and third connection vertical holes EH3 that are (e.g., electrically) connected to the second connection vertical holes EH2 and penetrate one or both of the third stack structure ST3 and the third planarized dielectric layer 125. The first connection vertical holes EH1 may further penetrate the second source conductive pattern SCP2 and the dummy dielectric pattern 101p, 103p, and 105p. The first connection vertical holes EH1 may further penetrate a portion of the second substrate 100.

The cell contact plugs CPLG, the through contact plugs TPLG, the peripheral contact plugs PPLG, and the dummy vertical structures DVS may each include a metal pattern FM and a barrier pattern BM on (e.g., surrounding) a sidewall of the metal pattern FM. According to some embodiments, the barrier pattern BM may surround or not surround a bottom surface of the metal pattern FM. The metal pattern FM and the barrier pattern BM may include, for example, a metallic material. The metal pattern FM may include, for example, titanium, tantalum, ruthenium, cobalt, manganese, tungsten, nickel, and/or copper. The barrier pattern BM may include, for example, a double layer or a mixture layer other than the double layer, which double or mixture layer may include, for example, titanium, titanium nitride, tantalum, tantalum nitride, ruthenium, cobalt, manganese, tungsten nitride, nickel, nickel boride, and/or titanium/titanium nitride. It is exemplarily explained that the dummy vertical structure DVS includes a metallic material, but the present inventive concepts are not limited thereto and the dummy vertical structure DVS may be formed of a dielectric material. The cell contact plugs CPLG, the through contact plugs TPLG, the peripheral contact plugs PPLG, and the dummy vertical structures DVS may each have a seam or a void therein.

The cell contact plugs CPLG, the through contact plugs TPLG, the peripheral contact plugs PPLG, and the dummy vertical structures DVS may each have a lateral surface in contact with the first dummy dielectric pattern 101p and the third dummy dielectric pattern 105p. In contrast, the lateral surface of each of the cell contact plugs CPLG, the through contact plugs TPLG, the peripheral contact plugs PPLG, and the dummy vertical structures DVS may be spaced apart from the second dummy dielectric pattern 103p across a sidewall dielectric pattern IIP. The cell contact plugs CPLG, the through contact plugs TPLG, the peripheral contact plugs PPLG, and the dummy vertical structures DVS may be in contact with the second substrate 100. The vertical channel structures VS, the cell contact plugs CPLG, the through contact plugs TPLG, the peripheral contact plugs PPLG, and the dummy vertical structures DVS may have their top surfaces located at substantially the same level. The vertical channel structures VS, the cell contact plugs CPLG, the through contact plugs TPLG, the peripheral contact plugs PPLG, and the dummy vertical structures DVS may have their bottom surfaces located at substantially the same level.

The cell array contact region CNR may include lower through vias BVIA (e.g., electrically) connected to the cell contact plugs CPLG, the through contact plugs TPLG, and the peripheral contact plugs PPLG. The lower through vias BVIA may not be provided on locations that vertically overlap the dummy vertical structures DVS. For example, the lower through vias BVIA may not be (e.g., electrically) connected to the dummy vertical structures DVS. The lower through vias BVIA may penetrate the second substrate 100, the second lower dielectric layer 53, and the etch stop layer 52. The lower through vias BVIA may be (e.g., electrically) connected through the first openings OP1 to the landing pads LP.

Each of the lower through vias BVIA may include a metal pattern FM, a barrier pattern BM that surrounds the metal pattern FM, and a cavity POR inside the metal pattern FM. The cavity POR may be a seam or a void. Each of the lower through vias BVIA may be integrally connected to one of the cell contact plug CPLG, the through contact plug TPLG, and the peripheral contact plug PPLG. No boundary may be provided between the lower through via BVIA and one of the cell contact plug CPLG, the through contact plug TPLG, and the peripheral contact plug PPLG.

A lower dielectric pattern 61 may be provided to penetrate the second substrate 100 and the dummy dielectric pattern 101p, 103p, and 105p and to surround a lower portion of each of the cell contact plug CPLG, the through contact plug TPLG, the peripheral contact plug PPLG, and the dummy vertical structure DVS. The lower dielectric pattern 61 may further surround a portion of the lower through via BVIA. When viewed in plan, the lower dielectric pattern 61 may have, for example, a circular annular shape or a polygonal annular shape. The cell contact plugs CPLG, the through contact plugs TPLG, the peripheral contact plugs PPLG, and the dummy vertical structures DVS may each have a lower portion provided in an inner perimeter of the lower dielectric pattern 61. A space defined by the inner perimeter of the lower dielectric pattern 61 may vertically overlap a space defined by each of the first openings OP1. The lower dielectric pattern 61 may include, for example, one or more of silicon oxide, silicon nitride, and silicon oxynitride.

The sidewall dielectric pattern IIP and the lower dielectric pattern 61 may electrically insulate the cell contact plugs CPLG, the through contact plugs TPLG, and the dummy vertical structures DVS from the second substrate 100 and the gate electrodes EL1, EL2, and EL3. The planarized dielectric layer 120 and the dielectric pattern 61 may electrically insulate the peripheral contact plugs PPLG from the second substrate 100 and the gate electrodes EL1, EL2, and EL3. For example, the sidewall dielectric pattern IIP may be provided between the gate electrodes EL1, EL2, and EL3 and the cell contact plugs CPLG, between the gate electrodes EL1, EL2, and EL3 and the through contact plugs TPLG, and between the gate electrodes EL1, EL2, and EL3 and the dummy vertical structures DVS. The sidewall dielectric pattern IIP may electrically insulate the gate electrodes EL1, EL2, and EL3 below the pad parts PAD from the cell contact plugs CPLG, the through contact plugs TPLG, and the dummy vertical structures DVS. Each of the cell contact plugs CPLG may be (e.g., electrically) connected to one of the pad parts PAD. Each of the pad parts PAD may be electrically connected to the peripheral circuit structure PS through one of the cell contact plugs CPLG. Each of the cell contact plugs CPLG may not be connected to the gate electrodes EL1, EL2, and EL3 other than one of the gate electrodes EL1, EL2, and EL3 that includes the pad part PAD to which the cell contact plug CPLG is (e.g., electrically) connected. The through contact plugs TPLG, the peripheral contact plugs PPLG, and the dummy vertical structures DVS may not be connected to the pad parts PAD. Therefore, the cell contact plug CPLG may be electrically connected to only one of the gate electrodes EL1, EL2, and EL3 that are vertically stacked, which only one of the gate electrodes EL1, EL2, and EL3 is located at the same level as that of the pad part PAD to which the cell contact plug CPLG is (e.g., electrically) connected. In contrast, the through contact plugs TPLG, the peripheral contact plugs PPLG, and the dummy vertical structures DVS may not be connected to any of the gate electrodes EL1, EL2, and EL3.

The cell contact plugs CPLG, through contact plugs TPLG, the peripheral contact plugs PPLG may be electrically connected to each other through the lower through vias BVIA and the peripheral circuit structure PS that includes the landing pads LP. The sidewall dielectric pattern IIP may include, for example, one or more of silicon oxide, silicon nitride, and silicon oxynitride.

Unless otherwise specified below, the description of the cell contact plugs CPLG is applicable to the through contact plugs TPLG, the peripheral contact plugs PPLG, and the dummy vertical structures DVS.

Referring to FIGS. 6A, 7A, and 7D, each of the cell contact plugs CPLG may include a pillar part PIP and a first protrusion part PTP1. The pillar part PIP may be a segment that extends in the third direction D3 from a lower portion of the cell contact plug CPLG. The first protrusion part PTP1 may be a segment that protrudes from the pillar part PIP in a horizontal direction defined by the first direction D1 and the second direction D2. The first protrusion part PTP1 and the pillar part PIP may be integrally formed into a single unitary piece. For example, no boundary may be provided between the first protrusion part PTP1 and the pillar part PIP. An outer sidewall of the pillar part PIP and a top surface of the first protrusion part PTP1 may be connected to each other on a bottom surface of a lowermost one of the first interlayer dielectric layers ILD1. The outer sidewall of the pillar part PIP and a bottom surface of the first protrusion part PTP1 may be connected to each other on a top surface of the third dummy dielectric pattern 105p. When viewed in plan, the first protrusion part PTP1 may have, for example, a circular annular shape or a polygonal annular shape. The top surface of the first protrusion part PTP1 may be located at a level the same as that of the top surface SCP2a of the second source conductive pattern SCP2 and that of a top surface of the lower dielectric pattern 61. The bottom surface of the first protrusion part PTP1 may be located at a level the same as that of the bottom surface SCP2b of the second source conductive pattern SCP2. The top surface of the first protrusion part PTP1 may be in contact with the lowermost one of the first interlayer dielectric layer ILD1. A lateral surface of the first protrusion part PTP1 may be in contact with the lower dielectric pattern 61. The bottom surface of the first protrusion part PTP1 may be in contact with the third dummy dielectric pattern 105p. A distance in the first direction D1 or the second direction D2 from the outer sidewall of the pillar part PIP to an outer sidewall of the first protrusion part PTP1 may be different on the top and bottom surfaces of the first protrusion part PTP1. However, the first protrusion part PTP1 may have the same maximum width in the first direction D1 or the second direction D2 from a point of one outer sidewall thereof to a point of another outer sidewall thereof.

Referring to FIGS. 6A, 7B, and 7D, the cell contact plug CPLG may have a pillar part PIP and a second protrusion part PTP2 that protrudes from the pillar part PIP in a horizontal direction defined by the first direction D1 and the second direction D2. The second protrusion part PTP2 and the pillar part PIP may be integrally formed into a single unitary piece. For example, no boundary may be provided between the second protrusion part PTP2 and the pillar part PIP. An outer sidewall of the pillar part PIP and a top surface of the second protrusion part PTP2 may be connected to each other on an interface between the first stack structure ST1 and the second stack structure ST2. The outer sidewall of the pillar part PIP and a bottom surface of the second protrusion part PTP2 may be connected to each other on a bottom surface of an uppermost one of the first interlayer dielectric layers ILD1. When viewed in plan, the second protrusion part PTP2 may have, for example, a circular annular shape or a polygonal annular shape. A distance in the first direction D1 or the second direction D2 from the outer sidewall of the pillar part PIP to an outer sidewall of the second protrusion part PTP2 may be different on the top and bottom surfaces of the second protrusion part PTP2. The second protrusion part PTP2 may have the same maximum width in the first direction D1 or the second direction D2 from a point of one outer sidewall thereof to a point of another outer sidewall thereof. The second protrusion part PTP2 may be provided on a location adjacent to an interface between the first stack structure ST1 and the second stack structure ST2 or an interface between the second stack structure ST2 and the third stack structure ST3. The top surface of the second protrusion part PTP2 may be located at a level substantially the same as that of the top surface of the first stack structure ST1 or that of the top surface of the second stack structure ST2. For example, the top surface of the second protrusion part PTP2 may be located at a level substantially the same as that of a top surface of the uppermost one of the first interlayer dielectric layers ILD1 or that of a top surface of an uppermost one of the second interlayer dielectric layers ILD2. The top surface of the second protrusion part PTP2 may be located at a level substantially the same as that of the top surface of the first planarized dielectric layer 121 or that of the top surface of the second planarized dielectric layer 123.

The second protrusion part PTP2 provided on a location adjacent to an interface between the first and second stack structures ST1 and ST2 may have a bottom surface located at a level higher than that of a top surface of an uppermost one of the first gate electrodes EL1. The second protrusion part PTP2 provided on a location adjacent to an interface between the second and third stack structures ST2 and ST3 may have a bottom surface located at a level higher than that of a top surface of an uppermost one of the second gate electrodes EL2.

When viewed in vertical section, the second protrusion part PTP2 may be provided in the uppermost one of the first interlayer dielectric layers ILD1 or in the uppermost one of the second interlayer dielectric layer ILD2. The top surface of the second protrusion part PTP2 may be in contact with the sidewall dielectric pattern IIP, and may not be in contact with any of the second gate electrode EL2 and the third gate electrode EL3.

At a level of the interface between the first and second stack structures ST1 and ST2 or between the second and third stack structures ST2 and ST3, each of the vertical channel structures VS may have a first width W1, or a maximum width in the first direction D1 or the second direction D2. In this description, the first width W1 is defined as a maximum width in the first direction D1 or the second direction D2 of each vertical channel structure VS.

At the level of the bottom surface of the second protrusion part PTP2, the pillar part PIP of each of the cell contact plugs CPLG may have a second width W2 or a maximum width in the first direction D1 or the second direction D2. In this description, the second width W2 is defined as a maximum width in the first direction D1 or the second direction D2 of each cell contact plug CPLG.

At the level of the top surface of the second protrusion part PTP2, the second protrusion part PTP2 of each of the cell contact plugs CPLG may have a third width W3 or a maximum distance in the first direction D1 or the second direction D2 from a point of one outer sidewall of the second protrusion part PTP2 to a point of another sidewall of the second protrusion part PTP2. For example, when viewed in plan, the third width W3 may be given to a maximum diameter at an outer perimeter of the second protrusion part PTP2. In this description, the third width W3 is defined as a maximum width in the first direction D1 or the second direction D2 of the second protrusion part PTP2.

The second width W2 and the third width W3 may each be greater than the first width W1. The third width W3 may be greater than the second width W2. For example, the first width W1 may range from about 110 nm to about 130 nm, the second width W2 may range from about 150 nm to about 300 nm, and the third width W3 may range from about 200 nm to about 340 nm.

Referring to FIGS. 6A, 7C, and 7D, each of the pad parts PAD may include a lower part DP and an upper part UP on the lower part DP. The lower part DP may be a segment that extends from a corresponding one of the gate electrodes EL1, EL2, and EL3. The upper part UP may be a segment that protrudes from the lower part DP in the third direction D3 or in a direction away from the second substrate 100.

The second protrusion part PTP2 may be spaced apart in the third direction D3 from the upper part UP of the pad part PAD. The second protrusion part PTP2 may not be in contact with the pad part PAD. The bottom surface of the second protrusion part PTP2 may be located at the level higher than that of a top surface of the pad part PAD (e.g., a top surface of the upper part UP of the pad part PAD) adjacent the second protrusion part PTP2.

Referring to FIGS. 6A, 6B, 7B, and 8, the top surfaces of the dummy vertical structures DVS may each have a circular shape, an oval shape, a bar shape, or any other suitable shapes.

The dummy vertical structures DVS may be disposed on circumferences of the cell contact plugs CPLG and on circumferences of the through contact plugs TPLG. When the dummy vertical structures DVS have their oval top surfaces, on each pad part PAD, major axes of the dummy vertical structures DVS may be disposed in different directions from each other. A plurality of dummy vertical structures DVS may be provided between neighboring cell contact plugs CPLG or between neighboring through contact plugs TPLG.

At a level of a bottom surface of the second protrusion part PTP2 in each of the dummy vertical structures DVS, the pillar part PIP of each of the dummy vertical structures DVS may have a fourth width W4 or a maximum width in the first direction D1 or the second direction D2. In this description, the fourth width W4 is defined as a maximum width in the first direction D1 or the second direction D2 of the pillar part PIP of each of the dummy vertical structures DVS.

At a level of a top surface of the second protrusion part PTP2 in each of the dummy vertical structures DVS, the second protrusion part PTP2 of each of the dummy vertical structures DVS may have a fifth width W5 or a maximum distance in the first direction D1 or the second direction D2 from a point of one outer sidewall of the second protrusion part PTP2 to a point of another sidewall of the second protrusion part PTP2. For example, when viewed in plan, the fifth width W5 may be given to a maximum diameter of an outer perimeter of the second protrusion part PTP2 of each of the dummy vertical structures DVS. In this description, the fifth width W5 is defined as a maximum width in the first direction D1 or the second direction D2 of the second protrusion part PTP2.

When viewed in plan, a sixth width W6 may be defined as a distance from a center of the cell contact plug CPLG to a center of the dummy vertical structure DVS. A seventh width W7 may be defined as a minimum horizontal distance from the second protrusion part PTP2 of the cell contact plug CPLG to the second protrusion part PTP2 of the dummy vertical structure DVS adjacent to the cell contact plug CPLG. Referring together to FIGS. 7B and 8, for example, the second width W2 may be the same as the fourth width W4. The third width W3 may be the same as the fifth width W5. The seventh width W7 may be the same as a value obtained by subtracting the third width W3 or the fifth width W5 from the sixth width W6. The seventh width W7 may be equal to or greater than about 15 nm.

According to the present inventive concepts, when viewed in plan, a value obtained by subtracting the third width W3 that is a maximum width in the first direction D1 or the second direction D2 of the second protrusion part PTP2 of each of the cell contact plugs CPLG from the sixth width W6 that is a distance between a center of the cell contact plug CPLG and a center of the dummy vertical structure DVS may be the same as the seventh width W7 that is a minimum horizontal distance from the second protrusion part PTP2 of the cell contact plug CPLG to the second protrusion part PTP2 of the dummy vertical structure DVS adjacent to the cell contact plug CPLG. The seventh width W7 may be equal to or greater than about 15 nm. Therefore, as the cell contact plug CPLG and the dummy vertical structure DVS are prevented from an electrical short-circuit caused by contact therebetween, a three-dimensional semiconductor memory device may improve in reliability and electrical properties.

Referring to FIGS. 6A and 6B, a fourth interlayer dielectric layer 130 may be provided on the third stack structure ST3, and a fifth interlayer dielectric layer 140 may be provided on the fourth interlayer dielectric layer 130. In the cell array region CAR, the fifth interlayer dielectric layer 140 may be provided thereon with bit lines BL that run across the stack structure ST and extend in the second direction D2. The bit lines BL may be electrically connected to the vertical channel structures VS through lower and upper bit-line contact plugs BLCPa and BLCPb.

In the cell array contact region CNR, the fifth interlayer dielectric layer 140 may be provided thereon with conductive lines CL that run across the stack structure ST and extend in the second direction D2. The conducive lines CL may be (e.g., electrically) connected through conductive contact plugs LCT to the cell contact plugs CPLG, the through contact plugs TPLG, and the peripheral contact plugs PPLG. The cell contact plugs CPLG, the through contact plugs TPLG, and the peripheral contact plugs PPLG may be electrically connected to each other through the conductive lines CL.

FIGS. 9, 10, 11, 12, 13, 14, 15, and 16 illustrate cross-sectional views taken along line A-A′ of FIG. 5, showing a method of fabricating a three-dimensional semiconductor memory device according to some embodiments of the present inventive concepts.

Referring to FIG. 9, a peripheral circuit structure PS may be formed on a first substrate 10 that includes a device isolation layer 11.

The formation of the peripheral circuit structure PS may include forming the peripheral transistors PTR on the first substrate 10, forming lower wiring lines LW1, LW2, and LW3, landing pads LP, and peripheral contact plugs PCP (e.g., electrically) connected to the peripheral transistors PTR, and forming a lower dielectric layer 50.

The peripheral transistors PTR, such as row and column decoders, page buffers, and control circuits, may be formed on the first substrate 10. The peripheral transistors PTR may include metal oxide semiconductor (MOS) transistors each of which uses the first substrate 10 as a channel.

The lower dielectric layer 50 may include a single or plurality of stacked dielectric layers on (e.g., cover) the peripheral transistors PTR. The lower dielectric layer 50 may include a first lower dielectric layer 51, a second lower dielectric layer 53, and an etch stop layer 52 between the first and second lower dielectric layers 51 and 53. The lower dielectric layer 50 may include, for example, a silicon oxide layer, a silicon nitride layer, a silicon oxynitride layer, and/or a low-k dielectric layer.

The formation of the lower wiring lines LW1, LW2, and LW3, the landing pads LP, and the peripheral contact plugs PCP may include forming the peripheral contact plugs PCP that penetrate portions of the lower dielectric layer 50, and forming the lower wiring lines LW1, LW2, and LW3 and the landing pads LP (e.g., electrically) connected to the peripheral contact plugs PCP.

The second lower dielectric layer 53 and the etch stop layer 52 may undergo a photolithography process and an etching process to form first openings OP1. For example, a photomask may be formed on the second lower dielectric layer 53, exposure and development processes may be performed on the photomask, and then a dry etching process may be executed to form the first openings OP1.

A second substrate 100 may be formed on the lower dielectric layer 50. The second substrate 100 may be formed by depositing a semiconductor material. The second substrate 100 may include, for example, silicon (Si), germanium (Ge), silicon germanium (SiGe), gallium arsenic (GaAs), indium gallium arsenic (InGaAs), aluminum gallium arsenic (AlGaAs), and/or a mixture thereof. The second substrate 100 may include a semiconductor doped with impurities or an intrinsic semiconductor with no impurities doped. The second substrate 100 may have a monocrystalline structure, an amorphous structure, and/or a polycrystalline structure. The second substrate 100 may fill the first openings OP1.

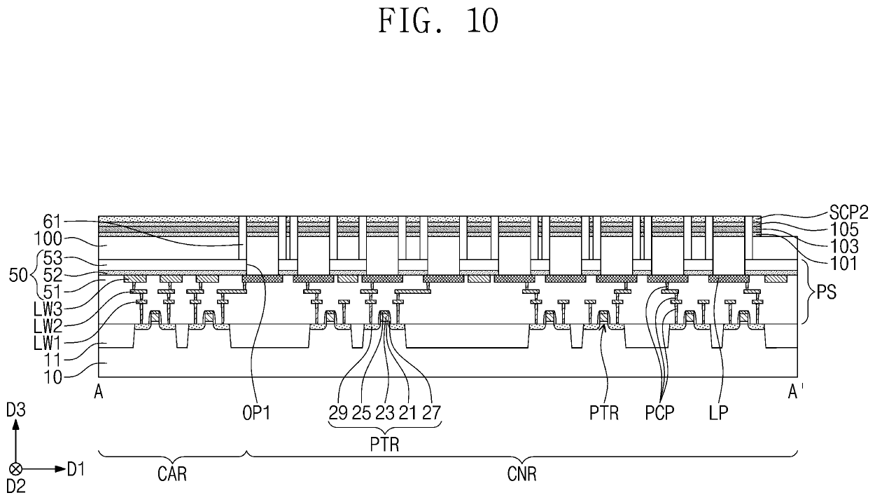

Referring to FIG. 10, a first dielectric layer 101, a second dielectric layer 103, and a third dielectric layer 105 may be sequentially stacked on the second substrate 100. The first dielectric layer 101 may be formed by thermally oxidizing a surface of the second substrate 100 or by depositing a silicon oxide layer, but not limited thereto. The second dielectric layer 103 may be formed of a material having an etch selectivity with respect to the first dielectric layer 101 and the third dielectric layer 105. For example, the second dielectric layer 103 may be a silicon nitride layer, a silicon oxynitride layer, a silicon carbide layer, and/or a silicon-germanium layer. The third dielectric layer 105 may be formed by depositing a silicon oxide layer, but not limited thereto.

A second source conductive pattern SCP2 may be formed (e.g., deposited) to have a uniform thickness on the third dielectric layer 105. The second source conductive pattern SCP2 may be, for example, a polysilicon layer doped with n-type impurities carbon (C), but not limited thereto.

A lower dielectric pattern 61 may be formed to penetrate the second source conductive pattern SCP2, the first, second, and third dielectric layers 101, 103, and 105, and the second substrate 100. When viewed in plan, the lower dielectric pattern 61 may have, for example, a circular annular shape or a polygonal annular shape. A space defined by an inner perimeter of the lower dielectric pattern 61 may vertically overlap a space defined by each of the first openings OP1. The formation of the lower dielectric pattern 61 may include forming a photomask, performing exposure and development processes on the photomask, and then performing a dry etching process. The lower dielectric pattern 61 may include, for example, silicon oxide, silicon nitride, and/or silicon oxynitride.

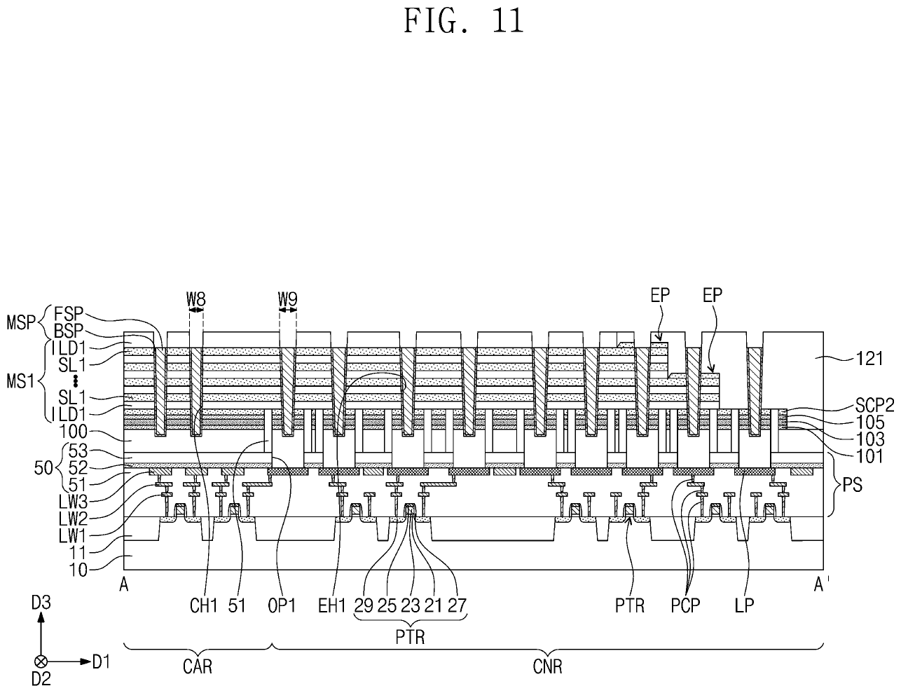

Referring to FIG. 11, a first mold structure MS1 may be formed on the second source conductive pattern SCP2. The formation of the first mold structure MS1 may include forming a thin film structure (not shown) where first interlayer dielectric layers ILD1 and first sacrificial layers SL1 are vertically and alternately stacked, and then repeatedly performing a patterning process on the thin film structure. Therefore, the first mold structure MS1 may have a stepwise structure in a cell array contact region CNR.

In the first mold structure MS1, the first sacrificial layers SL1 may be formed of a material that can be etched with an etch selectivity with respect to the first interlayer dielectric layers ILD1. For example, the first sacrificial layers SL1 may be formed of a dielectric material different from that of the first interlayer dielectric layers ILD1. The first sacrificial layers SL1 may be formed of the same material as that of the second dielectric layer 103. For example, the first sacrificial layers SL1 may be formed of a silicon nitride layer, and the first interlayer dielectric layers ILD1 may be formed of a silicon oxide layer.

Preliminary pad parts EP may be formed on an upper portion of the stepwise structure of the first mold structure MS1. The preliminary pad parts EP may be portions of the first sacrificial layers SL1, which portions of the first sacrificial layers SL1 are not covered with the first interlayer dielectric layers ILD1. The preliminary pad parts EP may be located at their levels that are lowered with an increase in distance from a cell array region CAR. For example, the farther the preliminary pad parts EP are from the cell array region CAR in the first direction D1, the lower the level of the preliminary pad parts EP may be.

The preliminary pad parts EP may increase in thickness. The thickness of the preliminary pad part EP may be greater than that of the first sacrificial layer SL1 between the first interlayer dielectric layers ILD1. Upper portions of the preliminary pad parts EP may protrude in a direction away from the second substrate 100 or in a third direction D3. A top surface of a preliminary pad part EP may be positioned on a lateral surface of a first interlayer dielectric layer ILD1 that is located immediately on a first sacrificial layer SL1 on which the preliminary pad part EP is disposed. The increasing thickness of the preliminary pad parts EP may include depositing an upper sacrificial layer on the first mold structure MS1, and removing a portion of the upper sacrificial layer to leave an upper sacrificial pattern on the top surfaces of the preliminary pad parts EP. The upper sacrificial pattern may include the same material as that of each of the first sacrificial layers SL1.

After the increasing thickness of the preliminary pad parts EP, a first planarized dielectric layer 121 may be formed in the cell array contact region CNR. The first planarized dielectric layer 121 may cover the stepwise structure of the first mold structure MS1. The first planarized dielectric layer 121 may cover top and lateral surfaced of the preliminary pad parts EP. A planarization process may be used to allow the first planarized dielectric layer 121 to have a top surface located at the same level as that of a top surface of the first mold structure MS1. The first planarized dielectric layer 121 may include, for example, a silicon oxide layer and/or a low-k dielectric layer.

First vertical channel holes CH1 may be formed to penetrate the first mold structure MS1, the second source conductive pattern SCP2, and the first, second, and third dielectric layers 101, 103, and 105, and first connection vertical holes EH1 may be formed to penetrate at least a portion of the first mold structure MS1 and/or the first planarized dielectric layer 121. The first vertical channel holes CH1 may further penetrate a portion of the second substrate 100. The first connection vertical holes EH1 may further penetrate the second source conductive pattern SCP2 and the first, second, and third dielectric layers 101, 103, and 105. The first connection vertical holes EH1 may further penetrate a portion of the second substrate 100. The first vertical channel holes CH1 and the first connection vertical holes EH1 may be formed simultaneously with each other. The first vertical channel holes CH1 and the first connection vertical holes EH1 may have their bottom surfaces that are substantially coplanar with each other.

Each of the first vertical channel holes CH1 may have an eighth width W8 that is a maximum width in a first direction D1 or a second direction D2 at a level of an interface between the first mold structure MS1 and a second mold structure MS2 which will be discussed below. Each of the first connection vertical holes EH1 may have a ninth width W9 in the first direction D1 or the second direction D2 at a level of the interface between the first mold structure MS1 and a second mold structure MS2 which will be discussed above. The eighth width W8 may be substantially the same as the first width W1 of FIG. 7B. The ninth width W9 may be substantially the same as the second width W2 of FIG. 2B.

The formation of the first vertical channel holes CH1 and the first connection vertical holes EH1 may include forming a photomask on the first mold structure MS1, performing exposure and development processes on the photomask, and then performing a dry etching process. The forming methods of the first vertical channel holes CH1 and the first connection vertical holes EH1, however, are not limited thereto.

Metal sacrificial patterns MSP may be formed to fill the first vertical channel holes CH1 and the first connection vertical holes EH1. The metal sacrificial pattern MSP may include a metal conductive sacrificial pattern FSP and a barrier metal sacrificial pattern BSP that surrounds the metal conductive sacrificial pattern FSP. The formation of the metal sacrificial pattern MSP may include forming a barrier metal sacrificial pattern layer (not shown), forming a metal conductive sacrificial pattern layer (not shown), performing a planarization process on the barrier metal sacrificial pattern layer and the metal conductive sacrificial pattern layer, and performing an etch-back process on the barrier metal sacrificial pattern layer and the metal conductive sacrificial pattern layer. The planarization process may continue until exposure of a top surface of an uppermost one of the first interlayer dielectric layers ILD1. The etch-back process may cause the metal sacrificial pattern MSP to have a top surface at the same level as that of a top surface of an uppermost one of the first sacrificial layers SL1. The metal conductive sacrificial pattern FSP may include, for example, titanium, tantalum, ruthenium, cobalt, manganese, tungsten, nickel, and/or copper. The barrier metal sacrificial pattern BSP may include, for example, titanium, titanium nitride, tantalum, tantalum nitride, ruthenium, cobalt, manganese, tungsten nitride, nickel, and/or nickel boride. The barrier metal sacrificial pattern BSP may include, for example, a double layer or a mixture layer other than the double layer, such as titanium/titanium nitride.

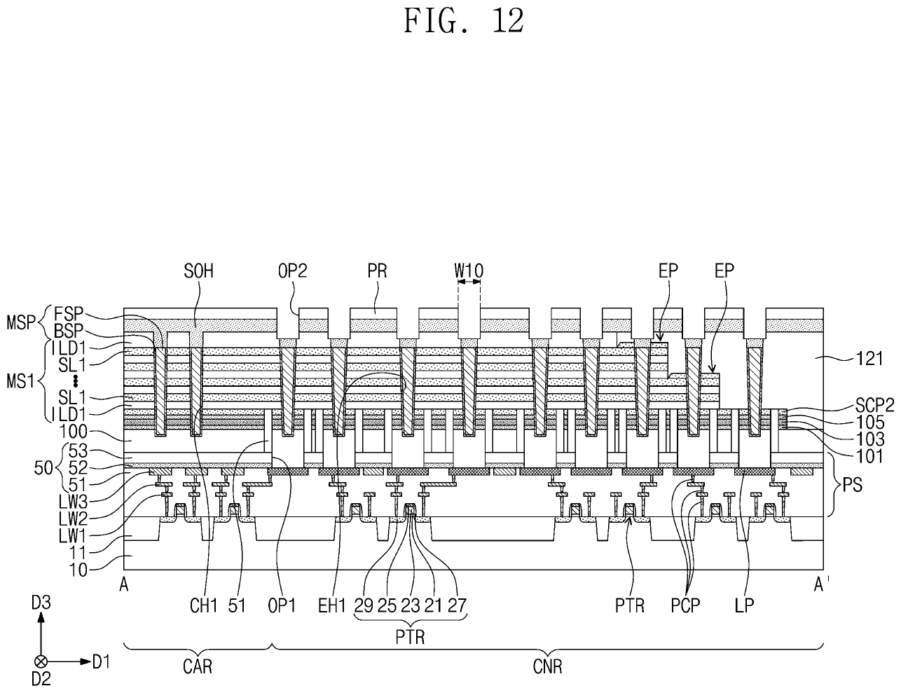

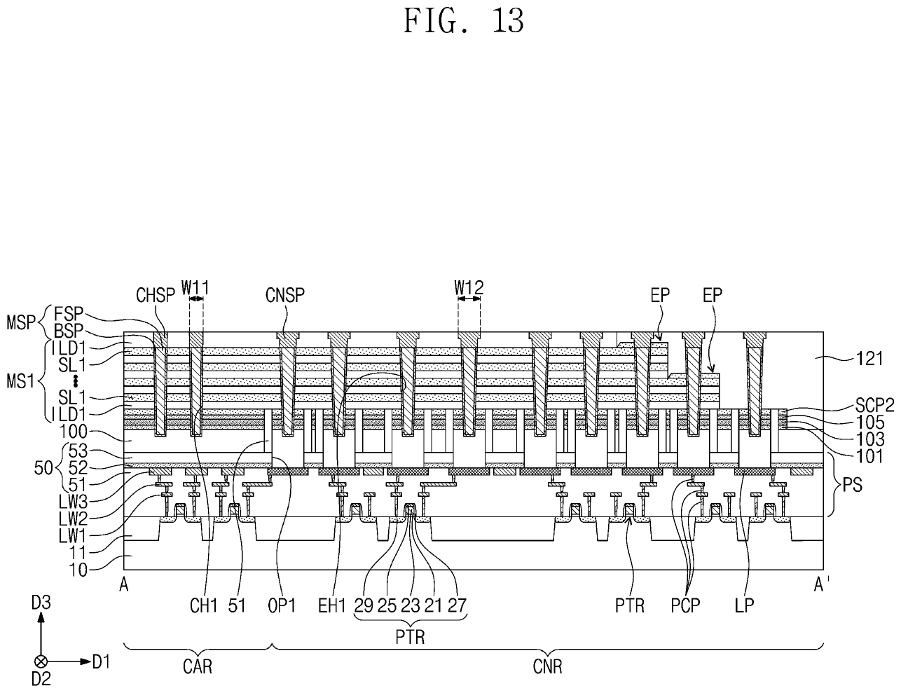

Referring to FIG. 12, a hardmask pattern SOH may be formed on the first mold structure MS1, and a photoresist pattern PR may be formed on the hardmask pattern SOH. The formation of the hardmask pattern SOH and the photoresist pattern PR may include forming a hardmask layer (not shown) on the first mold structure MS1, forming a photoresist layer (not shown) on the hardmask layer, performing exposure and development processes on the photoresist layer, and performing a dry etching process on the hardmask layer. The dry etching process may form second opening OP2 defined by the photoresist pattern PR and the hardmask pattern SOH.

The hardmask pattern SOH may cover the top surface of the uppermost one of the first interlayer dielectric layers ILD1. The uppermost one of the first interlayer dielectric layers ILD1 may be partially etched by the dry etching process performed on the hardmask layer. The hardmask pattern SOH may have a portion that vertically overlaps the metal sacrificial pattern MSP, and the portion of the hardmask pattern SOH may remain even after the dry etching process is performed.

In the cell array contact region CNR, the second openings OP2 may vertically overlap the first connection vertical holes EHL When viewed in plan, each of the second openings OP2 may have a circular shape or a polygonal shape, but not limited thereto. A tenth width W10 may be given as a maximum width in the first direction D1 or the second direction D2 of each of the second openings OP2. The tenth width W10 may be greater than the ninth width W9 of FIG. 11. The tenth width W10 may be substantially the same as the third width W3 of FIG. 7B.

Referring to FIG. 13, the hardmask pattern SOH and the photoresist pattern PR may be removed. A channel sacrificial pad pattern CHSP and a connection sacrificial pad pattern CNSP may be formed. In the cell array region CAR, the channel sacrificial pad pattern CHSP may vertically overlap the first vertical channel holes CH1. In the cell array contact region CNR, the connection sacrificial pad pattern CNSP may vertically overlap the first connection vertical holes EH1. At a level of a top surface of the channel sacrificial pad pattern CHSP, the channel sacrificial pad pattern CHSP may have an eleventh width W11 that is a maximum width in the first direction D1 or the second direction D2. At a level of a top surface of the connection sacrificial pad pattern CNSP, the connection sacrificial pad pattern CNSP may have a twelfth width W12 in the first direction D1 or the second direction D2. The eleventh width W11 may be substantially the same as the eighth width W8 of FIG. 11. The twelfth width W12 may be substantially the same as the tenth width W10 of FIG. 12. The connection sacrificial pad pattern CNSP may have a maximum width in the first direction D1 or the second direction D2, and the maximum width may be different at lower and upper portions thereof. The upper portion of the connection sacrificial pad pattern CNSP may be vertically spaced apart from the uppermost one of the first sacrificial layers SL1.

The formation of the channel sacrificial pad pattern CHSP and the connection sacrificial pad pattern CNSP may include forming a sacrificial pad layer (not shown) and performing a planarization process on the sacrificial pad layer. The planarization process may continue until exposure of the top surface of an uppermost one of the first interlayer dielectric layers ILD1.

The hardmask pattern SOH may include a spin-on hardmask. The channel sacrificial pad pattern CHSP and the connection sacrificial pad pattern CNSP may include, for example, titanium, titanium nitride, tantalum, tantalum nitride, ruthenium, cobalt, manganese, tungsten nitride, nickel, and/or nickel boride. The channel sacrificial pad pattern CHSP and the connection sacrificial pad pattern CNSP may include, for example, a double layer or a mixture layer other than the double layer, such as titanium/titanium nitride.

According to the present inventive concepts, the twelfth width W12 that is a maximum width in the first direction D1 or the second direction D2 of the connection sacrificial pad pattern CNSP may be greater than the ninth width W9 that is a maximum width in the first direction D1 or the second direction D2 of each of the first connection vertical holes EH1. Therefore, even though a central line of the first connection vertical hole EH1 and a central line of the second connection vertical hole EH2 are not aligned with each other in a vertical view when the second connection vertical holes EH2 are formed on the first connection vertical holes EH1, it may be possible to prevent a dry etching process from damaging the uppermost one of the first sacrificial layer SL1 in the first mold structure MS1. For the same reason, it may be possible to prevent a dry etching process from damaging an uppermost one of second sacrificial layers SL2 in a second mold structure MS2 which will be discussed below. In conclusion, a three-dimensional semiconductor memory device may improve in reliability and electrical properties.

In addition, the twelfth width W12 that is a maximum width in the first direction D1 or the second direction D2 of the connection sacrificial pad pattern CNSP may be greater than the ninth width W9 that is a maximum width in the first direction D1 or the second direction D2 of each of the first connection vertical holes EH1, while the eleventh width W11 that is a maximum width in the first direction D1 or the second direction D2 of the channel sacrificial pad pattern CHSP may be the same as the eighth width W8 that is a maximum width in the first direction D1 or the second direction D2 of each of the first vertical channel holes CH1. Therefore, an electrical short-circuit may be prevented between neighboring vertical channel structures VS. Accordingly, a three-dimensional semiconductor memory device may improve in reliability and electrical properties.

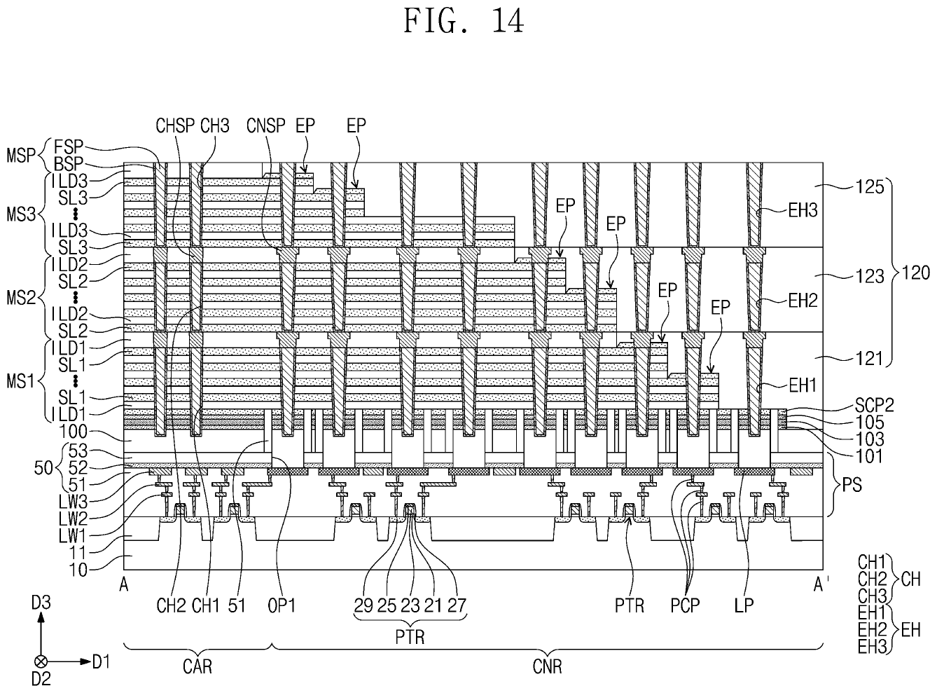

Referring to FIG. 14, the same method as that discussed with reference to FIGS. 11 to 13 may be used to form a second mold structure MS2 on the first mold structure MS1, a third mold structure MS3 on the second mold structure MS2, second and third vertical channel holes CH2 and CH3 on the first vertical channel holes CH1, second and third connection vertical holes EH2 and EH3 on the first connection vertical holes EH1, second and third planarized dielectric layers 123 and 125 on the first planarized dielectric layer 121, a metal sacrificial pattern MSP, a channel sacrificial pad pattern CHSP, and a connection sacrificial pad pattern CNSP. The first, second, and third planarized dielectric layers 121, 123, and 125 may constitute a planarized dielectric layer 120. The numbers of mold structures, vertical channel holes, connection vertical holes, and planarized dielectric layers in the vertical direction (e.g., third direction D3) described above are example embodiments and not limited thereto.

When viewed in vertical section, neither the channel sacrificial pad pattern CHSP nor the connection sacrificial pad pattern CNSP may be formed in the third mold structure MS3.

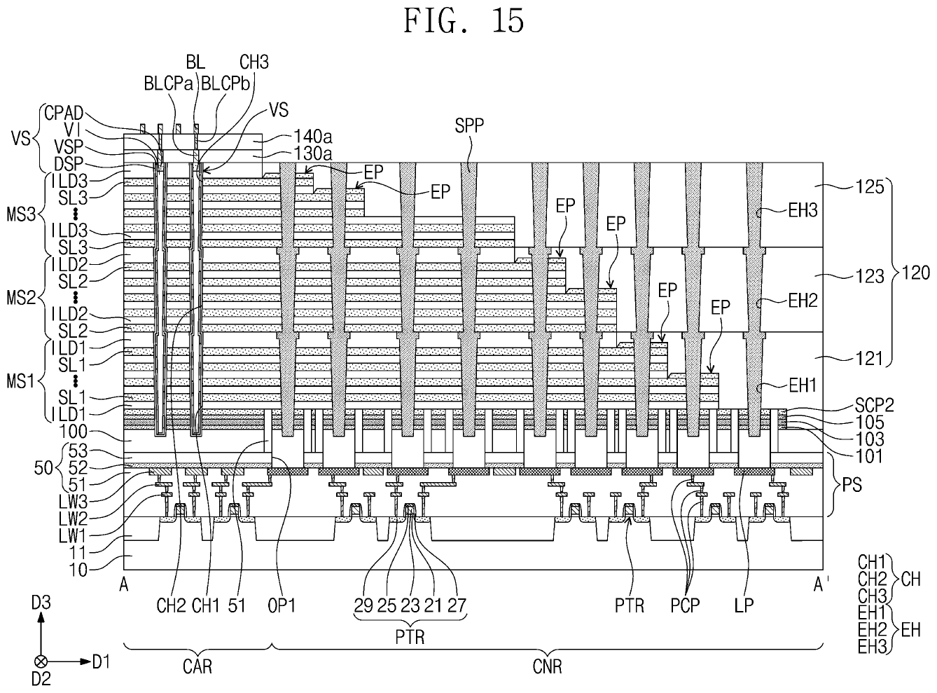

Referring to FIG. 15, the metal sacrificial pattern MSP may all be removed from the cell array region CAR and the cell array contact region CNR, and sacrificial poly patterns SPP may fill the connection vertical holes EH. The sacrificial poly pattern SPP may include, for example, polycrystalline silicon.

Afterwards, in a state that the cell array contact region CNR is screened by a photomask, a vertical channel structure VS, a preliminary fourth interlayer dielectric layer 130a, a preliminary fifth interlayer dielectric layer 140a, bit lines BL, and lower and upper bit-line contact plugs BLCPa and BLCPb may be formed in the cell array region CAR. The formation of the vertical channel structure VS may include sequentially depositing a data storage pattern DSP, a vertical semiconductor pattern VSP, and a buried dielectric pattern VI in the vertical channel holes CH. A chemical vapor deposition (CVD) process or an atomic layer deposition (ALD) method may be used to deposit the data storage pattern DSP on an inner wall of each of the vertical channel hole CH. A chemical vapor deposition (CVD) or atomic layer deposition (ALD) may be used to deposit the vertical semiconductor pattern VSP having a uniform thickness on the data storage pattern DSP. The buried dielectric pattern VI may be formed on an inner surface of the vertical semiconductor pattern VSP to fill an unoccupied portion of the vertical channel hole CH. A conductive pad CPAD may be formed on an upper portion of the vertical channel hole CH. The conductive pad CPAD may be an impurity-doped region or may be formed of a conductive material. The conductive pad CPAD may be electrically connected to the vertical semiconductor pattern VSP.

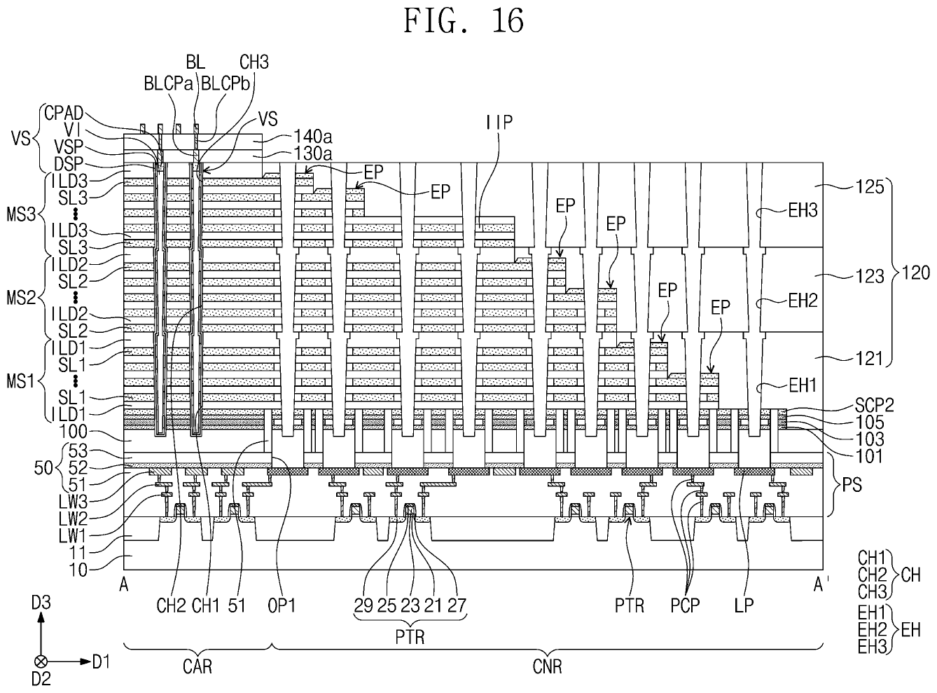

Referring to FIG. 16, in a state that the cell array region CAR is screened by a photomask, sacrificial poly patterns SPP may all be removed from the cell array contact region CNR. An isotropic etching process may be performed on the first, second, and third sacrificial layers SL1, SL2, and SL3 and the second dielectric layer 103 that are exposed by the connection vertical holes EH from which the sacrificial poly patterns SPP is removed. The isotropic etching process may use an etch recipe that have an etch selectivity with respect to the first, second, and third interlayer dielectric layers ILD1, ILD2, and ILD3, the second source conductive pattern SCP2, the first and third dielectric layers 101 and 105, and the second substrate 100. Therefore, the first, second, and third sacrificial layers SL1, SL2, and SL3 and the second dielectric layer 103 in the connection vertical holes EH may be partially removed to form recess regions (not shown). A sidewall dielectric pattern IIP may be formed to fill the recess regions.

Referring back to FIGS. 6A and 6B, a portion of the second source conductive pattern SCP2 and a portion of the second substrate 100 that vertically overlap the first opening OP1 may be removed through the connection vertical holes EH. The partial removal of the second source conductive pattern SCP2 and the second substrate 100 may include, for example, performing an isotropic etching process that uses an etch recipe having an etch selectivity with respect to the first, second, and third interlayer dielectric layers ILD1, ILD2, and ILD3, the first and third dielectric layers 101 and 105, the sidewall dielectric pattern IIP, and the planarized dielectric layer 120.

A barrier pattern BM and a metal pattern FM may be formed in the connection vertical holes EH. The barrier pattern BM and the metal pattern FM may be formed by sequentially depositing a barrier metal layer and a metal layer and then performing a planarization process. Therefore, cell contact plugs CPLG, through contact plugs TPLG, the peripheral contact plugs PPLG, and dummy vertical structures DVS may be formed in the cell array contact region CNR. In this step, lower through vias BVIA may also be formed at the same time. The lower through vias BVIA may be (e.g., electrically) connected to the landing pads LP.

A fourth interlayer dielectric layer 130 may be formed which extends from the preliminary fourth interlayer dielectric layer 130a, a fifth interlayer dielectric layer 140 may be formed which extends from the preliminary fifth interlayer dielectric layer 140a, and conductive lines CL and conductive contact plugs LCT may be formed.

Trenches (not shown) may be formed to run across the first, second, and third mold structures MS1, MS2, and MS3. The trenches may penetrate the second source conductive pattern SCP2 and the first, second, and third dielectric layers 101, 103, and 105, and may have their bottom surfaces located at a lower level than that of a top surface of the second substrate 100. Afterwards, in the cell array region CAR, the first, second, and third dielectric layers 101, 103, and 105 may be removed, and then a first source conductive pattern SCP1 may be formed in a space where the first, second, and third dielectric layers 101, 103, and 105 are removed, with the result that a source structure SC may be formed. In this step, in the cell array contact region CNR, the first, second, and third dielectric layers 101, 103, and 105 may partially remain to form a dummy dielectric pattern 101p, 103p, and 105p.

The first, second, and third sacrificial layers SL1, SL2, and SL3 may be removed, and then first, second, and third gate electrodes EL1, EL2, and EL3 may be formed in spaces where the first, second, and third sacrificial layers SL1, SL2, and SL3 are removed, with the result that a stack structure ST may be formed. Thereafter, first and second separation structures SS1 and SS2 may be formed in the trenches. Accordingly, a three-dimensional semiconductor memory device may be fabricated.

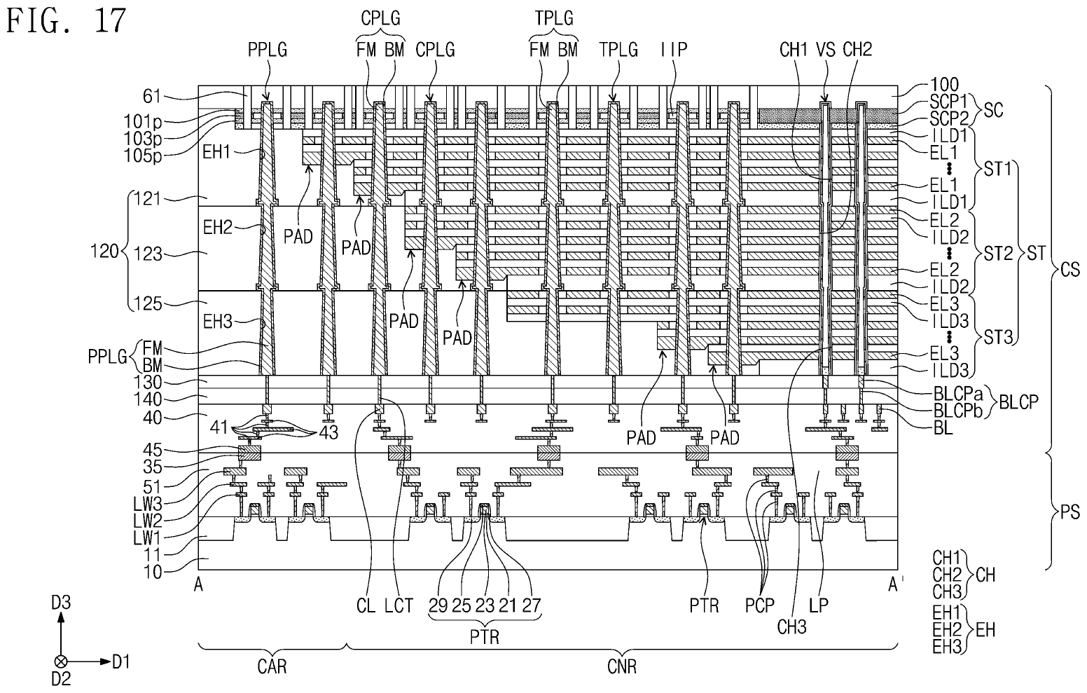

FIG. 17 illustrates a cross-sectional view taken along line A-A′ of FIG. 5, showing a three-dimensional semiconductor memory device according to some embodiments of the present inventive concepts. Except that described below, omission will be made to avoid a repetitive description with reference to FIGS. 5 to 8.

Referring to FIG. 17, a first substrate 10 may be provided thereon with a peripheral circuit structure PS including peripheral transistors PTR, peripheral contact plugs PCP, lower wiring lines LW1, LW2, and LW3 electrically connected through the peripheral contact plugs PCP to the peripheral transistors PTR, first bonding pads 35 electrically connected to the lower wiring lines LW1, LW2, and LW3, and a first lower dielectric layer 51 that surrounds the peripheral transistors PTR, the peripheral contact plugs PCP, the lower wiring lines LW1, LW2, and LW3, and the first bonding pads 35. The first lower dielectric layer 51 may not cover top surfaces of the first bonding pads 35. The first lower dielectric layer 51 may have a top surface substantially coplanar with those of the first bonding pads 35. Differently from that discussed with reference to FIGS. 6A and 6B, the peripheral circuit structure PS may not include any of the landing pads LP, the etch stop layer 52, and the second lower dielectric layer 53.

The peripheral circuit structure PS may be provided thereon with a cell array structure CS that includes second bonding pads 45, a stack structure ST, and a second substrate 100. The second substrate 100 may be provided on the stack structure ST. The stack structure ST may be provided between the second substrate 100 and the peripheral circuit structure PS.

The first lower dielectric layer 51 may be provided thereon with second bonding pads 45 in contact with the first bonding pads 35 of the peripheral circuit structure PS, connection contact plugs 41, connection circuit lines 43 electrically connected through the connection contact plugs 41 to the second bonding pads 45, and a connection dielectric layer 40 that covers the second bonding pads 45, the connection contact plugs 41, and the connection circuit lines 43. The connection dielectric layer 40 may include a plurality of stacked dielectric layers. For example, the connection dielectric layer 40 may include silicon oxide, silicon nitride, silicon oxynitride, and/or low-k dielectrics. The connection contact plugs 41 may have their widths in a first direction D1 or a second direction D2 that decrease in a third direction D3 (or decrease with increasing distance from the first substrate 10). The connection contact plugs 41 and the connection circuit lines 43 may include a conductive material, such as metal.

The connection dielectric layer 40 may not cover bottom surfaces of the second bonding pads 45. A bottom surface of the connection dielectric layer 40 may be substantially coplanar with those of the second bonding pads 45. The bottom surfaces of the second bonding pads 45 may be correspondingly in direct contact with the top surfaces of the first bonding pads 35. The first and second bonding pads 35 and 45 may include metal, such as copper (Cu), tungsten (W), aluminum (Al), nickel (Ni), and/or tin (Sn). For example, the first and second bonding pads 35 and 45 may include copper (Cu). The first and second bonding pads 35 and 45 may comprise a single unitary shape without any interface therebetween. The first and second bonding pads 35 and 45 are illustrated to have their sidewalls aligned with each other, but the present inventive concepts are not limited thereto, and when viewed in plan, the first and second bonding pads 35 and 45 may have their sidewalls spaced apart from each other.

The connection dielectric layer 40 may be provided on its upper portion with bit lines BL and conductive lines CL in contact with the connection contact plugs 41. A fifth interlayer dielectric layer 140 and a fourth interlayer dielectric layer 130 may be sequentially provided on the connection dielectric layer 40, and a stack structure ST and a planarized dielectric layer 120 may be provided on the fourth interlayer dielectric layer 130.

The stack structure ST may include a third stack structure ST3, a second stack structure ST2, and a first stack structure ST1 that are sequentially stacked on the fourth interlayer dielectric layer 130. The planarized dielectric layer 120 may include a third planarized dielectric layer 125, a second planarized dielectric layer 123, and a first planarized dielectric layer 121 that are sequentially stacked on the fourth interlayer dielectric layer 130. First gate electrodes EL1 of the first stack structure ST1, second gate electrodes EL2 of the second stack structure ST2, and third gate electrodes EL3 of the third stack structure ST3 may have their lengths in the first direction D1 that increase with increasing distance from the first substrate 10. The first, second, and third gate electrodes EL1, EL2, and EL3 may have their sidewalls that are spaced apart at a certain interval along the first direction D1 or the second direction D2. A lowermost one of the third gate electrodes EL3 in the third stack structure ST3 may have a length in the first direction D1 less than any other of the third gate electrodes EL3 in the third stack structure ST3, a lowermost one of the second gate electrodes EL2 in the second stack structure ST2 may have a length in the first direction D1 less than any other of the second gate electrodes EL2 in the second stack structure ST2, and a lowermost one of the first gate electrodes EL1 in the first stack structure ST1 may have a length in the first direction D1 less than any other of the first gate electrodes EL1 in the first stack structure ST1. Likewise the first, second, and third gate electrodes EL1, EL2, and EL3, first, second, and third interlayer dielectric layers ILD1, ILD2, and ILD3 may have their lengths in the first direction D1 that increase with increasing distance from the first substrate 10.

A source structure SC and a dummy dielectric pattern 101p, 103p, and 105p may be provided on the first stack structure ST1. The source structure SC may include a second source conductive pattern SCP2 and a first source conductive pattern SCP1 that are sequentially stacked. The dummy dielectric pattern 101p, 103p, and 105p may include a third dummy dielectric pattern 105p, a second dummy dielectric pattern 103p, and a first dummy dielectric pattern 101p that are sequentially stacked.

A second substrate 100 may be provided on the source structure SC and the dummy dielectric pattern 101p, 103p, and 105p. For example, the stack structure ST may be interposed between the second substrate 100 and the peripheral circuit structure PS. Unlike that shown in FIG. 6A, the first opening OP1 may not be present, and the lower through vias BVIA may not be provided.

As the cell array structure CS is bonded onto the peripheral circuit structure PS, it may be possible to increase a cell capacity per unit area of a three-dimensional semiconductor memory device according to the present inventive concepts. In addition, as the peripheral circuit structure PS and the cell array structure CS are manufactured separately and then bonded to each other, the peripheral transistors PTR may be prevented from being damaged due to various heat treatment processes, and accordingly, it may be possible to improve reliability and electrical properties of a three-dimensional semiconductor memory device according to the present inventive concepts.

According to some embodiments of the present inventive concepts, when viewed in plan, a value obtained by subtracting a maximum width in a first direction of a protrusion part of each of cell contact plugs from a distance between a center of the cell contact plug and a center of a dummy vertical structure may be the same as a minimum horizontal distance from the protrusion part of the cell contact plug to a protrusion part of the dummy vertical structure adjacent to the cell contact plug. The minimum horizontal distance may be equal to or greater than about 15 nm. Therefore, as the cell contact plug and the dummy vertical structure are prevented from an electrical short-circuit caused by contact therebetween, a three-dimensional semiconductor memory device may improve in reliability and electrical properties.

A maximum width in the first or second direction of a connection sacrificial pad pattern may be greater than a maximum width in the first or second direction of each of connection vertical holes. Therefore, even though a central line of each first connection vertical hole in a first mold structure is not aligned with a central line of each second connection vertical hole in a second mold structure, it may be possible to prevent a dry etching process from damaging an uppermost one of first sacrificial layers in the first mold structure. For the same reason, it may be possible to prevent a dry etching process from damaging an uppermost one of second sacrificial layers in the second mold structure. In conclusion, a three-dimensional semiconductor memory device may improve in reliability and electrical properties.

In addition, a maximum width in the first or second direction of a connection sacrificial pad pattern may be greater than a maximum width of each first connection vertical hole, while a maximum width in the first or second direction of a channel sacrificial pad pattern may be the same as a maximum of each first vertical channel hole. Therefore, an electrical short-circuit may be prevented between neighboring vertical channel structures. Accordingly, a three-dimensional semiconductor memory device may improve in reliability and electrical properties.

Although the present invention has been described in connection with the some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive. It should also be noted that in some alternate implementations, the steps of the method of manufacturing herein may occur out of the order. For example, two steps described in succession may in fact be executed substantially concurrently or the steps may sometimes be executed in the reverse order. Moreover, the steps of method may be separated into multiple steps and/or may be at least partially integrated. Finally, other steps may be added/inserted between the steps that are illustrated, and/or the steps may be omitted without departing from the scope of the present invention.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. As used herein, the term “and/or” includes any and all combinations of one or more of the associated listed items. Moreover, the symbol “/” will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A three-dimensional semiconductor memory device, comprising:
a first substrate;
a peripheral circuit structure on the first substrate; and
a cell array structure on the peripheral circuit structure, the cell array structure including a cell array region and a cell array contact region,
wherein the cell array structure includes:
a second substrate;
a stack structure including a first stack structure and a second stack structure that are stacked on the second substrate, each of the first and second stack structures including interlayer dielectric layers and gate electrodes that are alternately disposed;
a vertical channel structure in the cell array region, the vertical channel structure penetrating at least a portion of the stack structure and a portion of the second substrate; and
a cell contact plug in the cell array contact region, the cell contact plug penetrating at least a portion of the stack structure and a portion of the second substrate,
wherein the cell contact plug includes:
a first pillar part that extends in a direction perpendicular to a top surface of the first substrate; and
a first protrusion part that protrudes from the first pillar part in a first direction parallel to the top surface of the first substrate, wherein the first protrusion part and the first pillar part comprise a single unitary piece,
wherein the first protrusion part has a circular annular shape or a polygonal annular shape when viewed in plan,
wherein a top surface of the first protrusion part is at a same distance as a distance of a top surface of the first stack structure from the top surface of the first substrate,
wherein, the first protrusion part has a first width at the top surface of the first protrusion part, and the first width is a maximum diameter at an outer perimeter of the first protrusion part,
wherein, the vertical channel structure has a second width at an interface between the first stack structure and the second stack structure, and the second width is a maximum width of the vertical channel structure in the first direction, and
wherein the first width is greater than the second width.

2. The three-dimensional semiconductor memory device of claim 1, wherein
the first pillar part has a third width at a bottom surface of the first protrusion part, and the third width is a maximum width of the first pillar part in the first direction, and
wherein the third width is greater than the second width.

3. The three-dimensional semiconductor memory device of claim 2, further comprising a dummy vertical structure spaced apart from the cell contact plug, the dummy vertical structure penetrates at least a portion of the stack structure and a portion of the second substrate in the cell array contact region,
wherein the dummy vertical structure includes:
a second pillar part that extends in the direction perpendicular to the top surface of the first substrate; and
a second protrusion part that protrudes in the first direction from the second pillar part, wherein the second protrusion part and the second pillar part comprise a single unitary piece,
wherein the second protrusion part has a circular annular shape or a polygonal annular shape when viewed in plan,
wherein a top surface of the second protrusion part is at a same distance as the top surface of the first protrusion part from the top surface of the first substrate,
wherein, the second pillar part has a fourth width at a bottom surface of the second protrusion part, and the fourth width is a maximum width of the second pillar part in the first direction, and
wherein the fourth width is greater than the second width.

4. The three-dimensional semiconductor memory device of claim 3, wherein
the second protrusion part has a fifth width at the top surface of the second protrusion part, and the fifth width is a maximum diameter at an outer perimeter of the second protrusion part,
wherein the fourth width is same as the third width, and
wherein the fifth width is same as the first width.

5. The three-dimensional semiconductor memory device of claim 1, wherein
each of the first stack structure and the second stack structure has a stepwise structure in the cell array contact region,
each of the gate electrodes has a pad part that is thicker than another part of the gate electrodes in the direction perpendicular to the top surface of the first substrate,
the pad part protrudes in a direction away from a top surface of the second substrate, and
the first protrusion part is spaced apart from the pad part in the direction perpendicular to the top surface of the first substrate.

6. The three-dimensional semiconductor memory device of claim 1, wherein a bottom surface of the first protrusion part is at a greater distance than a bottom surface of an uppermost one of the interlayer dielectric layers in the first stack structure from the top surface of the first substrate.

7. The three-dimensional semiconductor memory device of claim 1, further comprising a source structure between the second substrate and the stack structure, the source structure including a first source conductive pattern and a second source conductive pattern that are stacked on the second substrate,
wherein the vertical channel structure includes a vertical semiconductor pattern electrically connected to the first source conductive pattern.

8. The three-dimensional semiconductor memory device of claim 7, wherein the cell contact plug further includes a second protrusion part that is spaced apart from the first protrusion part in the direction perpendicular to the top surface of the first substrate,
wherein the second protrusion part protrudes in the first direction from the first pillar part,
wherein the second protrusion part and the first pillar part comprise a single unitary piece,
wherein the second protrusion part has a circular annular shape or a polygonal annular shape when viewed in plan,
wherein the second source conductive pattern extends from the cell array region to the cell array contact region, and
wherein a top surface of the second protrusion part is at a same distance as a top surface of the second source conductive pattern from the top surface of the first substrate.

9. The three-dimensional semiconductor memory device of claim 1, further comprising a lower through via that penetrates the second substrate and is electrically connected to the cell contact plug,
wherein the peripheral circuit structure includes peripheral transistors and landing pads electrically connected to the peripheral transistors, and
wherein the lower through via is electrically connected to the landing pads.

10. The three-dimensional semiconductor memory device of claim 9, further comprising a lower dielectric pattern between the second substrate and the cell contact plug,
wherein the lower dielectric pattern has a circular annular shape or a polygonal annular shape when viewed in plan.

11. The three-dimensional semiconductor memory device of claim 10, further comprising a source structure between the second substrate and the stack structure, the source structure including a first source conductive pattern and a second source conductive pattern that are stacked on the second substrate,
wherein the lower dielectric pattern extends between the source structure and the cell contact plug.

12. The three-dimensional semiconductor memory device of claim 9, wherein the cell array structure further includes a first dummy dielectric pattern, a second dummy dielectric pattern, and a third dummy dielectric pattern that are stacked on the second substrate in the cell array contact region,
wherein the cell contact plug is in contact with the first and third dummy dielectric patterns and is spaced apart from the second dummy dielectric pattern.

13. The three-dimensional semiconductor memory device of claim 1, wherein the cell array structure further includes:
a through contact plug that penetrates at least a portion of the stack structure and is spaced apart from the gate electrodes; and
a peripheral contact plug that is spaced apart from the stack structure in the first direction and penetrates at least a portion of the second substrate,
wherein the through contact plug includes a second pillar part and a second protrusion part that protrudes from the second pillar part in the first direction,
wherein the peripheral contact plug includes a third pillar part and a third protrusion part that protrudes from the third pillar part in the first direction, and
wherein a top surface of each of the second and third protrusion parts is at the same distance as the distance of the top surface of the first protrusion part from the top surface of the first substrate.

14. A semiconductor memory device, comprising:
a first substrate;
a peripheral circuit structure on the first substrate; and
a cell array structure on the peripheral circuit structure, the cell array structure including a cell array region and a cell array contact region,
wherein the cell array structure includes:
a stack structure including a first stack structure and a second stack structure that are stacked on the peripheral circuit structure, each of the first and second stack structures including interlayer dielectric layers and gate electrodes that are alternately disposed;
a second substrate on the second stack structure;
a cell contact plug in the cell array contact region, the cell contact plug penetrating at least a portion of the stack structure and a portion of the second substrate; and
a dummy vertical structure spaced apart from the cell contact plug, the dummy vertical structure penetrating at least a portion of the stack structure and a portion of the second substrate in the cell array contact region,
wherein the cell contact plug includes:
a first pillar part that extends in a direction perpendicular to a top surface of the first substrate; and
a first protrusion part that protrudes from the first pillar part in a first direction parallel to the top surface of the first substrate, wherein the first protrusion part and the first pillar part do not have a boundary therebetween,
wherein the dummy vertical structure includes:
a second pillar part that extends in the direction perpendicular to the top surface of the first substrate; and
a second protrusion part that protrudes in the first direction from the second pillar part, the second protrusion part and the second pillar part do not have a boundary therebetween,
wherein each of the first and second protrusion parts has a circular annular shape or a polygonal annular shape when viewed in plan,
wherein, when viewed in plan, the semiconductor memory device has a first width that is a distance from a center of the cell contact plug to a center of the dummy vertical structure,
wherein the first protrusion part has a second width that is a maximum diameter of an outer perimeter of the first protrusion part,
wherein the semiconductor memory device has a third width that is a minimum horizontal distance from the first protrusion part to the second protrusion part, and
wherein the third width is equal to a difference between the first width and the second width.

15. The semiconductor memory device of claim 14, wherein a top surface of the first protrusion part and a top surface of the second protrusion part are at a same distance as a distance of a bottom surface of the second stack structure from the top surface of the first substrate.

16. The semiconductor memory device of claim 14, further comprising a lower dielectric pattern that penetrates the second substrate and surrounds the cell contact plug when viewed in plan,
wherein the lower dielectric pattern has a circular annular shape or a polygonal annular shape when viewed in plan.

17. The semiconductor memory device of claim 14, wherein the peripheral circuit structure includes first bonding pads, and
wherein the cell array structure includes:
second bonding pads in contact with the first bonding pads;
connection contact plugs and connection circuit lines that are electrically connected to the second bonding pads; and
a connection dielectric layer that surrounds the second bonding pads, the connection contact plugs, and the connection circuit lines.

18. The semiconductor memory device of claim 14, further comprising: a first dummy dielectric pattern, a second dummy dielectric pattern, and a third dummy dielectric pattern that are stacked on the second stack structure in the cell array contact region, wherein the first to third dummy dielectric patterns are between the second substrate and the second stack structure, and
wherein the cell contact plug is spaced apart from the second dummy dielectric pattern in the first direction by a sidewall dielectric pattern.

19. An electronic system, comprising:
a three-dimensional semiconductor memory device that includes a first substrate, a peripheral circuit structure on the first substrate, and a cell array structure on the peripheral circuit structure, the cell array structure including a cell array region and a cell array contact region; and
a controller electrically connected through an input/output pad to the three-dimensional semiconductor memory device, the controller controlling the three-dimensional semiconductor memory device,
wherein the cell array structure includes:
a second substrate;
a first stack structure and a second stack structure that are stacked on the second substrate, each of the first and second stack structures including interlayer dielectric layers and gate electrodes that are alternately disposed;
a vertical channel structure in the cell array region, the vertical channel structure penetrating at least a portion of the first and second stack structures and a portion of the second substrate; and
a cell contact plug in the cell array contact region, the cell contact plug penetrating at least a portion of the first and second stack structures and a portion of the second substrate,
wherein the cell contact plug includes:
a pillar part that extends in a direction perpendicular to a top surface of the first substrate; and
a protrusion part that protrudes from the pillar part in a first direction parallel to the top surface of the first substrate, wherein the protrusion part and the pillar part are a single unitary piece,
wherein a top surface of the protrusion part is at a same distance as a distance of a top surface of an uppermost one of the interlayer dielectric layers in the first stack structure from the top surface of the first substrate, and
wherein a bottom surface of the protrusion part is at a greater distance than a distance of a bottom surface of the uppermost one of the interlayer dielectric layers in the first stack structure from the top surface of the first substrate.

20. The electronic system of claim 19, wherein
an uppermost one of the gate electrodes in the first stack structure includes a pad part that protrudes in a direction away from the second substrate, and
the bottom surface of the protrusion part is higher than a top surface of the pad part with respect to the top surface of the first substrate.
